(19) United States
(12) Patent Application Publication
(10) Pub. No.: US 2026/0086144 A1
(43) Pub. Date: Mar. 26, 2026

(54) TEMPERATURE-AWARE BUILT-IN SELF-TEST (BIST) CONTROL SYSTEM FOR SELECTIVELY CONTROLLING ACTIVATION OF BIST CIRCUITS IN A PROCESSOR-BASED SYSTEM TO MAINTAIN TEMPERATURE LIMIT, AND RELATED METHODS

(71) Applicant: QUALCOMM Incorporated, San Diego, CA (US)

(72) Inventors: Dipti Ranjan Pal, Irvine, CA (US); Deepak Agrawal, San Diego, CA (US); Aseem Pandey, San Diego, CA (US); Shih-Hsin Jason Hu, San Diego, CA (US)

(21) Appl. No.: 18/895,669

(22) Filed: Sep. 25, 2024

(51) Int. Cl. G01R 31/28

(52) U.S. Cl. CPC G01R 31/2874; G01R 31/2879

(57) ABSTRACT

Temperature-aware built-in self-test (BIST) control system for selectively controlling activation of BIST circuits in a processor-based system to maintain temperature limit and related methods. The temperature-aware BIST control system is configured to selectively control the number of BIST circuits in the processor-based system activated during the same time based on a temperature limit indicator related to a sensed temperature(s) in the processor-based system and whether such is within a defined temperature threshold(s) and/or temperature change rate threshold(s), which may be programmable. In this manner, the safety manager circuit can dynamically and selectively control the number of BIST circuits activated based on temperature according to the BIST control policy(ies) to reduce or avoid circuit failures due to excess temperature, while at the same time maximizing the staggering (i.e., overlapping) of BIST circuit activations to maximize testing speed.

### FIELD OF THE DISCLOSURE

The field of the disclosure relates to built-in self-test (BIST) systems that are built into components in a processor-based system, such as a logic BIST (LBIST) circuit to perform internal testing in a processor, and a memory BIST (MBIST) circuit for performing internal testing of memory.

### BACKGROUND

Processors, also known as microprocessors, perform computational tasks in a wide variety of applications. One or more processors can be provided in a processor-based system that includes other supporting components, such as memory and interface circuits, for supporting tasks carried out by the processors according to executed program (i.e., software and/or firmware) instructions. For example, such processors can include a generalized central processing unit (CPU) and/or specialized processors such as a graphics processing unit (GPU), neural signal processor (NSP), or digital signal processor (DSP) to name a few examples. The processors and supporting peripheral components of the processor-based system can be provided in the same semiconductor die packaged in an integrated circuit (IC) chip, known as a system-on-a-chip (SoC). System memory that is sized to be the full address size of the processor-based system such as dynamic random access memory (DRAM), is typically provided external to the IC chip of the SoC due to size and because of such external memory being highly specialized to be manufactured efficiently by a smaller number of companies as well as its packaging constraints. A SoC has the advantage of the processors being co-located on the same die and in close signal length proximity to each other and to the supporting peripheral components to increase performance speed and in a smaller area than providing these components on separate dies and respective IC chips that are mounted to a circuit board having signal traces coupling external pins of the ICs to each other to provide connectivity.

It may be desired to also include a safety island (SAIL) subsystem in a processor-based system. The SAIL subsystem is a dedicated subsystem designed to handle safety-critical tasks independently from the main processor(s) in the processor-based system. This isolation ensures that even if a processor(s) fails or experiences a fault, the safety-critical functions of the processor-based system can continue to operate. It may be particularly critical for a processor-based system to include a SAIL subsystem where functional safety is critical, such as automotive systems, industrial control systems, and medical devices. A SAIL subsystem can be configured with its own dedicated resources, such as a microcontroller, memory, and peripherals, separate from those used by the main processors, further ensuring reliability. For example, a SAIL subsystem may include a safety manager circuit that may be a microcontroller or other hardware circuit configured to control the operation of the processor-based system when transitioning between a safe operational mode (“safe mode”) and regular operational mode (“regular mode”). For example, if the processor-based system is deployed as an IC chip in an automotive environment, the safety manager circuit can be configured to transition to a regular mode where applications critical to safety are not being performed, such as an in-vehicle infotainment (IVI) application(s). On the other hand, in the same automotive environment, the safety manager circuit can be configured to transition to a safe mode when critical vehicle control applications are to be executed (e.g., a driver assistance application) to prevent the uploading of files or signals from outside of its IC chip as a safety and/or security measure. The processor-based system may also be configured for the safety manager circuit to boot up in a safe mode in response to a power assertion or reset for the safety reasons.

When entering a safe operational mode, the safety manager circuit can be configured to check operating parameters, monitor voltage and power, check temperature, and perform or control testing to detect failures. Thereafter, the safety manager circuit can be configured to disallow uploading of data into the processor-based system and allow the processor(s) to execute normal workloads in the safe mode. When it is desired to transition from a safe mode to a regular mode, the safety manager circuit can once again allow uploading of data into the processor-based system. As part of transitioning into a safe mode, the safety manager circuit can be configured to interface with built-in self-test (BIST) circuits built into different components of the processor-based system to initiate built-in testing of circuits in such components to detect failures therein. Examples of BIST circuits include logic BIST (LBIST) circuits built into the individual processor(s) and memory BIST (MBIST) circuits built into memories (e.g., multiple levels of cache memories, last level cache (LLC) memory, and system memory). The BIST circuits are configured to perform testing with internal test generation and response analysis of their respective components separately from normal operations of these components. Thus, for example, in a boot-up operation wherein a processor may not yet be fully functional, an LBIST circuit in a processor can still be controlled and function to perform internal testing of logic circuits in the processor. The results of these built-in tests can be reported back the safety manager circuit to be analyzed to determine if the processor-based system has passed testing such that the processor-based system can safely enter into a safe mode for performing critical applications. The processor-based system may also support dynamic switching between safe and regular modes requiring dynamic BIST support by the BIST circuits.

### SUMMARY OF THE DISCLOSURE

Aspects disclosed herein include a temperature-aware built-in self-test (BIST) control system for selectively controlling activation of BIST circuits in a processor-based system to maintain temperature limit. Related methods of controlling built-in self-testing in the processor-based system are also disclosed. The processor-based system can be included on a semiconductor die packaged in an integrated circuit (IC) chip as a system-on-a-chip (SoC). The processor-based system includes one or more processors and supporting components (e.g., cache memory, system memory, interface circuits) to perform tasks according to program code executed by the processor(s). Certain components of the processor-based system, such as the processor(s) and memory, include BIST circuits configured to be activated in a test mode of the processor-based system to perform built-in self-tests of their internal circuits to detect circuit failures. The processor-based system also includes a safety manager circuit that may be part of a safety island (SAIL) subsystem in the processor-based system, and that is configured to handle safety-critical tasks independently from the processor(s) in isolation. This ensures that if a processor(s) fails or experiences a fault, the safety-critical functions (e.g., critical vehicle control functions in an automotive application) of the processor-based system can continue to operate without being affected. The safety manager circuit is interfaced with BIST circuits to control their operation to perform built-in self-tests in a test mode, such as in response to a boot-up operation of the processor-based system and/or the processor-based system entering a safe operating mode (“safe mode”). Operation of the BIST circuits cause the tested circuits in their respective components to be activated to perform testing thus consuming dynamic power. It may be desired to configure the BIST circuits to concurrently operate to test circuits in their respective components, such as during a boot-up operation, to minimize the time needed to perform testing. However, concurrently activating the BIST circuits may cause the processor-based system to exceed a temperature limit thus causing circuit failures and in a manner that causes permanent circuit failure and/or that cannot be distinguished from normal failures. BIST circuits typically cause their respective components to consume more dynamic power during testing than during a normal, non-testing mode, thus generating additional heat, since the BIST circuits are typically designed to activate a greater percentage of circuits in its respective components to achieve a high testing coverage.

In exemplary aspects, to reduce or avoid circuit failures due to excess temperature during testing, the processor-based system includes a temperature-aware BIST control system to selectively control the number of BIST circuits activated during the same time in the processor-based system. The temperature-aware BIST control system is configured to selectively control the number of BIST circuits activated during the same time based on a temperature limit indicator related to a sensed temperature(s) in the processor-based system and whether such is within a defined temperature threshold(s), which may be programmable. The temperature-aware BIST control system includes a safety manager circuit interfaced with a thermal manager circuit(s), which is located within and assigned to a designated area, subsystem(s), or component(s) of the processor-based system. The thermal manager circuit is interfaced with a temperature sensor(s) located within or in close proximity to a designated area, subsystem, or component to sense the temperature(s) of such designated subsystem or component, because different areas, subsystems, or components can be affected differently by the dissipation of heat from the operation of the BIST circuits. The thermal manager circuit is configured to receive temperature readings from its interfaced temperature sensor(s) and generate a temperature limit indicator indicating if the sensed temperature and/or the temperature change rate is within one or more defined temperature thresholds and/or temperature change rate thresholds, which may be programmable as an example. In a test mode, the safety manager circuit is configured to obtain the temperature limit indicator(s) from the thermal manager circuit(s) and selectively control the number of BIST circuits activated during the same time based on the temperature limit indicator(s). In an example, the temperature-aware BIST control system can be configured to selectively control the number of BIST circuits activated based on applying the detected temperature(s) to a BIST control policy(ies). In this manner, the safety manager circuit can dynamically and selectively control the number of BIST circuits activated based on temperature according to the BIST control policy(ies) to reduce or avoid circuit failures due to excess temperature, while at the same time maximizing the staggering (i.e., overlapping) of BIST circuit activations to maximize testing speed. The safety manager circuit can also be configured to dynamically obtain an updated temperature limit indicator(s) from the thermal manager circuit(s) on an ongoing basis during a test mode to be able to dynamically selectively control (e.g., increase and decrease) the number of BIST circuits activated based on the local temperature limit indicator(s).

As one example, in a test mode of the processor-based system, if a temperature limit indicator(s) indicates a temperature and/or temperature change rate exceeding a defined maximum temperature threshold and/or defined maximum temperature change rate threshold, the BIST control policy applied by the safety manager circuit to the temperature limit indicator(s) may call for selectively activating only one (1) BIST circuit in the processor-based system at a given time at the cost of increased testing time, but for the benefit of reduced power consumption to reduce the chance of circuit failure due to excess temperature. As another example, if the temperature limit indicator(s) indicates a temperature or temperature change rate not exceeding a defined lower temperature threshold and/or defined maximum temperature change rate threshold, the BIST control policy applied by the safety manager circuit to the temperature limit indicator(s) may call for activating all of BIST circuits in the processor-based system during the same time to perform testing to maximize testing speed. As another example, if the temperature limit indicators indicate a temperature or temperature change rate in between the defined lower and maximum temperature thresholds and/or defined lower and maximum temperature change rate thresholds, the BIST control policy applied by the safety manager circuit to the temperature limit indicator(s) may call for activating less than all of BIST circuits in the processor-based system to perform testing at a given time to manage power consumption consistent with the temperature limit indicators.

In an example, the thermal manager circuits in the temperature-aware BIST control system include one or more local thermal manager circuits, which are assigned and within or co-located in close proximity to a respective, designated subsystem(s) or component(s) of the processor-based system. The local thermal manager circuits are each interfaced with a temperatures sensor(s) located within or in close proximity to its designated subsystem or component in the processor-based system to sense the temperature(s) of such designated subsystem or component, because different subsystems or components in the processor-based system can be affected differently by the dissipation of heat from the operation of the BIST circuits. The local thermal manager circuit is configured to receive temperature readings from its interfaced temperature sensor(s) and generate a local temperature limit indicator indicating if the sensed temperature is within one or more defined local thermal threshold limits and/or defined local temperature change rates, which may be programmable as an example. In a test mode, the safety manager circuit is configured to obtain the local temperature limit indicator(s) from the local thermal manager circuit(s) and selectively control the number of BIST circuits in the processor-based system activated during the same time based on the local temperature limit indicator(s). The temperature-aware BIST control system can also be configured to selectively control the operation of a BIST circuit in a subsystem or component assigned to the local thermal manager circuit(s) based on applying the local temperature limit indicator to a local BIST control policy(ies).

In another exemplary aspect, the thermal manager circuits in the temperature-aware BIST control system can include a central thermal manager circuit. The central thermal manager circuit can be designed to operate similarly to a local thermal manager circuit; however, the central thermal manager circuit is interfaced with a temperatures sensor(s) that is not necessarily specific to a particular subsystem or component of the processor-based system that includes a BIST circuit. For example, the central thermal manager circuit may be interfaced with a temperatures sensor(s) located in a specific area of a die of the processor-based system to sense temperature within that specific area that is affected by the operation of the BIST circuits in the processor-based system. For example, a certain area(s) of the die may be more susceptible to a hot spot(s) than another area(s), such that temperatures exceeding a defined thermal limit may cause a reduced performance or failure in a system component of the processor-based system, such as a power rail for example, or other component. In a test mode, the central thermal manager circuit is configured to receive a sensed temperature(s) from its interfaced temperature sensor(s) and generate a central temperature limit indicator indicating if the sensed temperature(s) is within one or more defined central temperature thresholds and/or defined central temperature change rate thresholds, which may be programmable as an example. The temperature-aware BIST control system can also be configured to selectively control the operation of a BIST circuit in a subsystem or component assigned to the central thermal manager circuit based on applying the central temperature limit indicator to a central BIST control policy(ies).

As another example, the safety manager circuit can be configured to selectively control the number of BIST circuits activated during the same time in the processor-based system and its subsystems and/or components in response to both a local temperature limit indicator(s) from a local thermal manager circuit(s) and a central temperature limit indicator from a central thermal manager circuit. The central thermal manager circuit may also be designed such that it is interfaced with a local thermal manager circuit(s) as an intermediate circuit between it and the safety manager circuit. In this example, the central thermal manager circuit can be configured to generate the central temperature limit indicator based on both the central temperature limit indicator generated by the central thermal manager circuit the local temperature limit indicator(s) generated by the local thermal manager circuit(s). In this manner, in an example, a single central temperature limit indicator can be obtained by the safety manager circuit indicative of a global temperature limit indicator (using a combination of the central temperature limit indicator and local temperature limit indicator(s)) to selectively control the number of BIST circuits activated during the same time in the processor-based system. The safety manager circuit may also be configured to obtain the local temperature limit indicator(s) from the local thermal manager circuit(s) and selectively control the BIST circuit(s) in the subsystem(s) or component(s) assigned to the local thermal manager circuit(s) based directly on the local temperature limit indicator(s).

In this regard, in one exemplary aspect, processor-based system comprising an IC is disclosed. The processor-based system includes a plurality of computing devices. Each computing device includes a plurality of BIST circuits each associated with a computing device of the plurality of computing devices. Each BIST circuit of the plurality of BIST circuits is configured to be activated to test its associated computing device. Each computing device also includes a BIST control system. The BIST control system includes a safety manager circuit configured to selectively control activation of the BIST circuit of each of the plurality of computing devices. The BIST control system also includes one or more thermal manager circuits. Each thermal manager circuit is configured to receive one or more temperatures sensed from one or more temperature sensors in the IC. Each thermal manager circuit is also configured to convert the received one or more temperatures to at least one of a maximum temperature and a temperature change rate. Each thermal manager circuit is also configured to compare the at least one of the maximum temperature and the temperature change rate to one or more temperature thresholds. Each thermal manager circuit is also configured to generate a temperature limit indicator based on the comparison of the at least one of the maximum temperature and the temperature change rate to the one or more temperature thresholds. The safety manager is configured to receive a test mode indicator indicating a test mode for the processor-based system. In response to the test mode indicator indicating the test mode, the safety manager is configured to selectively control the activation of the BIST circuit associated with each of the plurality of computing devices based on the temperature limit indicator generated by each of the one or more thermal manager circuits.

In another exemplary aspect, a method of controlling activation of BIST circuits in a processor-based system is disclosed. The processor-based system includes a plurality of computing devices and a plurality of BIST circuits each associated with a computing device of the plurality of computing devices and configured to be activated to test its associated computing device. The method includes receiving one or more temperatures sensed from one or more temperature sensors in an IC. The method also includes converting the received one or more temperatures to at least one of a maximum temperature and a temperature change rate. The method also includes comparing the at least one of the maximum temperature and the temperature change rate to one or more temperature thresholds. The method also includes generating a temperature limit indicator based on the comparison of the at least one of the maximum temperature and the temperature change rate to the one or more temperature thresholds. The method also includes receiving a test mode indicator indicating a test mode for the processor-based system. The method also includes, in response to the test mode indicator indicating the test mode, selectively controlling activation of one or more of the plurality of BIST circuits each associated with a computing device of the plurality of computing devices, based on the generated temperature limit indicator.

### BRIEF DESCRIPTION OF THE FIGURES

FIG. 1 is a block diagram of an exemplary processor-based system that can be provided in a system-on-a-chip (SoC), wherein the processor-based system includes a temperature-aware built-in self-test (BIST) control system configured to selectively control activation of a number of BIST circuits in different subsystems or components (e.g., processors, memory) activated during the same time, based on a temperature limit indicator(s) generated based on a sensed temperature(s) and/or temperature change rate(s) in the processor-based system to a temperature limit(s) to minimize staggering of BIST circuit activations to maximize testing speed while at the same time reducing or avoiding circuit failures due to excess temperature;

FIG. 2 is a block diagram of the processor-based system in FIG. 1 deployed in an automotive application, wherein a central processing unit (CPU) is configured to execute a virtual machine (VM) that includes driver assistance system (DAS) applications configured to be executed as critical applications in a safe mode, and also includes an in-vehicle infotainment (IVI) system with IVI applications configured to be executed as non-critical applications;

FIG. 3 is a block diagram of an exemplary thermal manager circuit assigned to a subsystem or component in the processor-based system in FIG. 1, wherein the thermal manager circuit is configured to receive a sensed temperature from its interfaced temperature sensor(s) and generate a temperature limit indicator indicating if the sensed temperature is within one or more defined thermal limits and/or temperature change rates, wherein the temperature limit indicator is accessible by the safety manager circuit configured to selectively control activation of a BIST circuit in the processor-based system;

FIG. 4 is flowchart illustrating an exemplary process of the temperature-aware BIST control system, such as in FIGS. 1 and 3, for controlling activation of a BIST circuit in a subsystem or component in the processor-based system, based on applying a BIST policy to the temperature limit indicator generated by the thermal manager circuit;

FIG. 5 is a block diagram of an exemplary a local thermal manager circuit assigned to a subsystem or component in the processor-based system in FIG. 1, wherein the local thermal manager circuit is configured to receive a sensed temperature from its interfaced temperature sensor(s) and generate a local temperature limit indicator indicating if the sensed temperature is within one or more defined local thermal limits and/or local temperature change rates, wherein the local temperature limit indicator is accessible by the safety manager circuit configured to selectively control activation of a BIST circuit in the assigned subsystem or component based on a local BIST control policy applied to the local temperature limit indicator;

FIG. 6 is a chart illustrating an exemplary local BIST control policy that can be used by the safety manager circuit, such as the safety manager circuit in FIG. 3, to selectively control activation of BIST circuits in the processor assigned to a local thermal manager circuit in FIG. 5, based on the local temperature threshold limit generated by the local thermal manager circuit;

FIG. 7 is a block diagram of an exemplary a central thermal manager circuit in the processor-based system in FIG. 1, wherein the central thermal manager circuit is configured to receive a sensed temperature(s) from its interfaced temperature sensor(s) and generate a central temperature limit indicator indicating if the sensed temperature(s) is within one or more defined central thermal limits and/or central temperature change rates, wherein the central temperature limit indicator is accessible by the safety manager circuit configured to selectively control the number of BIST circuits in the processor-based system activated during the same time based on a central BIST control policy applied to the central temperature limit indicator;

FIG. 8 is a chart illustrating an exemplary central BIST control policy that can be used by the safety manager circuit in FIG. 3 to selectively control the number of BIST circuits in the processor-based system activated during the same time, based on applying the central BIST control policy to the central temperature threshold limit generated by the central thermal manager circuit in FIG. 7;

FIG. 9 is a block diagram of an exemplary temperature-aware BIST control system that can be provided in the processor-based system in FIG. 1, that includes a plurality of local thermal manager circuits configured to generate local temperature limit indicators, a central thermal manager circuit configured to generate a central temperature limit indicator based on a sensed temperature(s) from a temperature sensor(s) and the local temperature limit indicators, wherein the central temperature limit indicator and local temperature limit indicators are accessible by the safety manager circuit configured to selectively control the number of BIST circuits in the processor-based system activated during the same time, based on a central BIST control policy and/or local BIST control policies applied to the respective central temperature limit indicator and local temperature limit indicators;

FIG. 10 is a block diagram of an exemplary processor-based system that includes a temperature-aware BIST control system, such as the temperature-aware BIST control systems in FIGS. 1, 3, 5, 7, and 9, configured to selectively control activation of BIST circuits in the processor-based system during the same time based on applying a BIST control policy(ies) to a temperature limit indicator(s) generated by a thermal manager circuit(s), to minimize staggering of BIST circuit activations to maximize testing speed while at the same time reducing or avoiding circuit failures due to excess temperature, and according to a process including, but not limited to, the exemplary process in FIG. 4; and

FIG. 11 is a block diagram of an exemplary wireless communications device that includes radio-frequency (RF) components, wherein any of the RF components can include a processor-based system that includes a temperature-aware BIST control system, such as the temperature-aware BIST control systems in FIGS. 1, 3, 5, 7, and 9, configured to selectively control activation of BIST circuits in the processor-based system during the same time based on applying a BIST control policy(ies) to a temperature limit indicator(s) generated by a thermal manager circuit(s), to minimize staggering of BIST circuit activations to maximize testing speed while at the same time reducing or avoiding circuit failures due to excess temperature, and according to a process including, but not limited to, the exemplary process in FIG. 4.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include a temperature-aware built-in self-test (BIST) control system for selectively controlling activation of BIST circuits in a processor-based system to maintain temperature limit. Related methods of controlling built-in self-testing in the processor-based system are also disclosed. In exemplary aspects, to reduce or avoid circuit failures due to excess temperature during testing, the processor-based system includes a temperature-aware BIST control system to selectively control the number of BIST circuits activated during the same time in the processor-based system. The temperature-aware BIST control system is configured to selectively control the number of BIST circuits activated during the same time based on a temperature limit indicator related to a sensed temperature(s) in the processor-based system and whether such is within a defined temperature threshold(s), which may be programmable. The temperature-aware BIST control system includes a safety manager circuit interfaced with a thermal manager circuit(s), which is assigned to a designated area, subsystem(s), or component(s) of the processor-based system. The thermal manager circuit is interfaced with a temperatures sensor(s) located within or in close proximity to a designated area, subsystem, or component to sense the temperature(s) of such designated subsystem or component, because different areas, subsystems, or components can be affected differently by the dissipation of heat from the operation of the BIST circuits. The thermal manager circuit is configured to receive temperature readings from its interfaced temperature sensor(s) and generate a temperature limit indicator indicating if the sensed temperature and/or the temperature change rate is within one or more defined temperature thresholds and/or temperature change rate thresholds, which may be programmable as an example.

In a test mode, the safety manager circuit is configured to obtain the temperature limit indicator(s) from the thermal manager circuit(s) and selectively control the number of BIST circuits activated during the same time based on the temperature limit indicator(s). In an example, the temperature-aware BIST control system can be configured to selectively control the number of BIST circuits activated based on applying the detected temperature(s) to a BIST control policy(ies). In this manner, the safety manager circuit can dynamically and selectively control the number of BIST circuits activated based on temperature according to the BIST control policy(ies) to reduce or avoid circuit failures due to excess temperature, while at the same time maximizing the staggering (i.e., overlapping) of BIST circuit activations to maximize testing speed. The safety manager circuit can also be configured to dynamically obtain an updated temperature limit indicator(s) from the thermal manager circuit(s) in an ongoing basis during a test mode to be able to dynamically selectively control (e.g., increase and decrease) the number of BIST circuits activated based on the local temperature limit indicator(s).

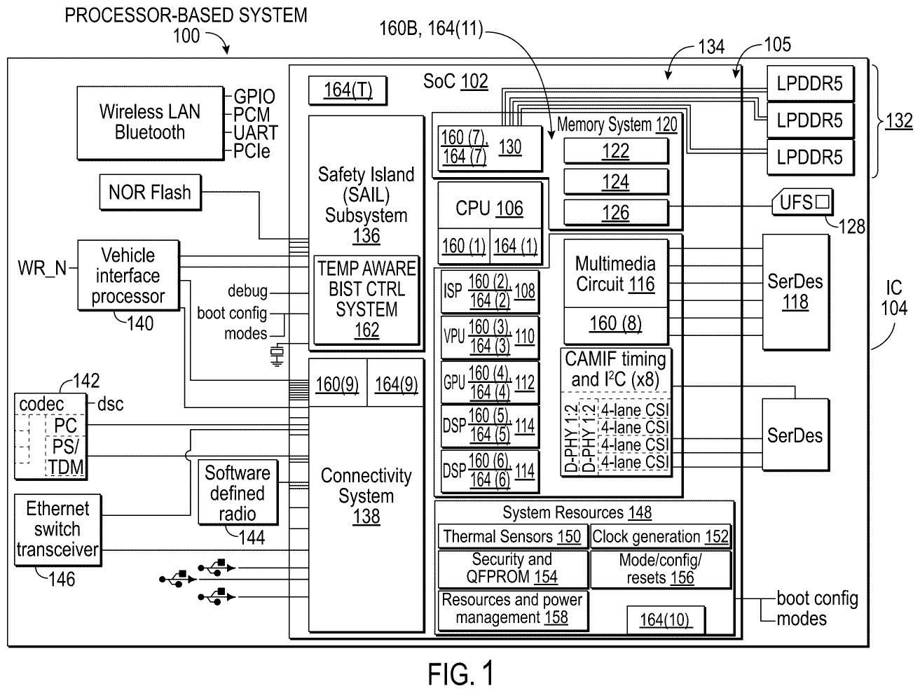

In this regard, FIG. 1 is a block diagram of an exemplary processor-based system 100 provided as a system-on-a-chip (SoC) 102. The SoC 102 is provided as an integrated circuit (IC) 104 in which multiple computing devices 105 are included in the same semiconductor die in the IC 104. As shown in FIG. 1, the SoC 102 includes a CPU 106 that includes one or more processors as computing devices 105 each with one or more CPU cores for executing program code to carry out tasks within the SoC 102. A benefit of providing the processor-based system 100 in the SoC 102 is that the SoC 102 can include other specialized processors on-chip that can be utilized by the CPU 106 to perform specialized tasks in a highly efficient manner. In this example, the SoC 102 includes an image signal processor (ISP) 108 which is a media processor configured to process image data that is captured from an imaging device interfaced with the SoC 102, such as a camera. The SoC 102 also includes a vector processing unit (VPU) 110, a graphic processing unit (GPU) 112, and digital signal processors (DSPs) 114. These processors may be shared computing resources that can be accessed through execution of an application by the CPU 106 to perform specific tasks.

With continuing reference to FIG. 1, the SoC 102 in this example also includes a multimedia circuit 116 as another computing device 105 that is configured to interface with an external serialization/de-serialization circuit 118 to stream media data in and out of the SoC 102. The multimedia circuit 116 is a shared computing resource in the SoC 102. The SoC 102 also includes a memory system 120 as another computing device 105 that includes a cache memory 122, internal memory 124, and a universal flash storage (UFS) interface circuit 126 for interfacing with an external flash memory drive 128 to send and receive data to be stored and/or accessed from the flash memory drive 128. The memory system 120 also includes a memory controller 130 that is configured to be used to provide access by the CPU 106 to the memory system 120, and to an external system memory 132 (e.g., dynamic random access memory (DRAM)) through a memory interface 134. The memory system 120 is a shared computing resource in the SoC 102. The SoC 102 also includes a safety island (SAIL) subsystem 136 that is configured to manage faults and control the rest of the SoC 102 to enable recovery from chip and signal failures. The SoC 102 also includes a connectivity system 138 that includes interface circuits configured to interface with external circuits, which in this example include a vehicle interface processor 140, a coded circuit 142, a software defined radio 144, and an ethernet switch/transceiver 146. For example, the SoC 102 may be designed specifically for a vehicle or automotive application to provide a computing resource to control vehicle functions through the vehicle interface processor 140. The connectivity system 138 is a shared computing resource in the SoC 102. The SoC 102 also includes system resources 148 that provide internal functions, such as thermal sensors 150 for sensing temperature in the SoC 102, clock generation circuits 152 for generating clock signals, a power management circuit 154 for regulating voltage and power supplied in the SoC 102, boot registers 156 for being configured for boot-up modes and reset operations, and security circuits 158 for providing security features and functions in the SoC 102.

One or more of the computing devices 105 in the SoC 102 may have an assigned or integrated BIST circuit 160(1)-160(B). For example, a BIST circuit 160(1)-160(B) can be incorporated into an assigned computing device 105 as an internal circuit. The BIST circuits 160(1)-160(B) are configured to perform testing of its assigned computing device 105 (i.e., the CPU 106, ISP 108, VPU 110, GPU 112, DSPs 114, memory system 120/memory controller 130, SoC 102) and its circuits with internal test generation and to perform response analysis of its assigned computing device 105 in the SoC 102 separately from normal operations of such computing device 105. In this example, the SAIL subsystem 136 includes a temperature-aware BIST control system 162 that is interfaced with the BIST circuits 160(1)-160(B). In a test mode, the temperature-aware BIST control system 162 controls activation of the BIST circuits 160(1)-160(B) to perform built-in self-tests of their respective components, such as in response to a boot-up operation of the processor-based system 100 and/or the processor-based system 100 entering into a safe operating mode (“safe mode”) where critical applications (e.g., vehicle control applications if the SoC 102 is deployed in a vehicle) will be executed that need assurance of the proper functioning of the processor-based system 100. For example, in a safe mode, the SAIL subsystem 136 may disallow uploading of data into the SoC 102 for safety reasons so that critical applications being executed by the CPU 106 are not subject to safety issues, or failures that may occur from outside access.

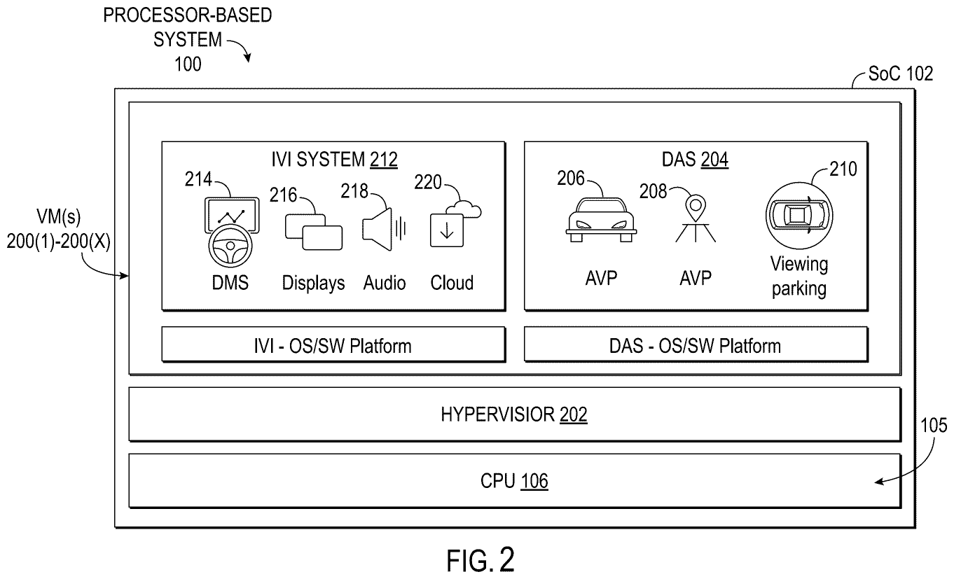

For example, FIG. 2 is a block diagram of the example processor-based system 100 in FIG. 1 deployed in a vehicle as an automotive environment and applications. The processor-based system 100 in FIG. 2 is shown as supporting multiple virtual machines VMs 200(1)-200(X) that are switched in and out of execution by the CPU 106 by a hypervisor 202. A first VM 200(1) includes driver assistance system (DAS) applications 204 that control vehicle functions and thus are critical applications that may only be allowed by the SAIL subsystem 136 to be executed by the CPU 106 when the processor-based system 100 is in a safe mode. The SAIL subsystem 136 may control the transition of the processor-based system 100 and its CPU 106 to enter a safe mode when the DAS applications 204 are to be executed by the CPU 106. In this example the DAS applications 204 include an automotive vision perception (AVP) application 206, a drive policy (DP) application 208, and a viewing parking application 210 that control critical functions of a vehicle. On the other hand, the first VM 200(1) can also include in-vehicle infotainment (IVI) system applications 212 that include non-critical applications as not controlling critical functions of a vehicle, such as a driver monitoring system (DMS) application 214, a display application 216, an audio application 218, and a cloud storage interface application 220. The SAIL subsystem 136 may be configured to not enforce entering into a safe mode when the IVI system applications 212 as non-critical applications are to be executed by the CPU 106.

With reference back to the processor-based system 100 in FIG. 1, operation of the BIST circuits 160(1)-160(B) cause the tested circuits in their assigned computing devices 105 to be activated to perform testing thus consuming dynamic power. The BIST circuits 160(1)-160(B) could be controlled in a test mode to concurrently operate to test circuits in their respective components, such as during a boot-up operation or entering a safe mode, to minimize the time needed to perform testing. However, concurrently activating the BIST circuits 160(1)-160(B) to perform testing concurrently or during the same time may cause the SoC 102 to exceed a temperature limit thus causing circuit failure and in a manner that causes permanent circuit failure and/or that cannot be distinguished from normal failures. This is because the BIST circuits 160(1)-160(B) typically cause their respective tested components to consume more dynamic power during testing than during a normal, non-testing mode, thus generating additional heat. The BIST circuits 160(1)-160(B) are typically designed to activate a greater percentage of circuits in their respective tested components to achieve a higher testing coverage.

As discussed in more detail below, to reduce or avoid circuit failures in the SoC 102 and thus the processor-based system 100 due to excess temperature during testing, the SoC 102 includes the temperature-aware BIST control system 162. For example, the temperature-aware BIST control system 162 can be part of the SAIL subsystem 136. The temperature-aware BIST control system 162 is configured to selectively control activation of the BIST circuits 160(1)-160(B) that operate during the same time in the SoC 102 in a test mode to reduce or avoid circuit failures due to excess temperature, while at the same time maximizing the staggering (i.e., overlapping) of BIST circuit 160(1)-160(B) activations to maximize testing speed. The processor-based system 100 may be placed in a test mode during a boot-up operation and/or when the processor-based system 100 transitions from a regular operating mode into a safe mode, as non-limiting examples. As discussed in more detail below, in a test mode, the temperature-aware BIST control system 162 circuit is configured to obtain the temperature limit indicator(s) from thermal manager circuits 164(1)-164(T) that are configured to receive temperature readings from interface temperature sensors that sense temperature(s) in their proximity and to generate temperature related information indicative of the sensed temperature(s). Some thermal manager circuits 164(1)-164(T) may be assigned to specific computing devices 105 to obtain the temperature of such computing devices 105, whereas other thermal manager circuits 164(1)-164(T) may be located in specific die areas of the die of the SoC 102 not assigned to a particular component to generate environmental temperature information for such specific die areas. The temperature of both specific computing devices 105 and in specific die areas of the SoC 102 can affect the proper operation of the processor-based system 100. Thus, in exemplary aspects, the temperature information generated by the thermal manager circuits 164(1)-164(T) can be used by the temperature-aware BIST control system 162 to determine how many BIST circuits 160(1)-160(B) are to be activated to operate during the same time to control temperature and related heat in the SoC 102.

If, in a test mode, the temperature information is such that all of the BIST circuits 160(1)-160(B) can be activated during the same time without risk of excess temperature in the SoC 102, the temperature-aware BIST control system 162 can control the activation of all the BIST circuits 160(1)-160(B) to operate during the same time. However, if, in a test mode, the temperature information is such that only a subset of the BIST circuits 160(1)-160(B) can be activated during the same time without risk of excess temperature in the SoC 102, the temperature-aware BIST control system 162 can selectively control the activation of a subset of the BIST circuits 160(1)-160(B) to operate during the same time. This can reduce or avoid circuit failures due to excess temperature, while at the same time maximizing the staggering (i.e., overlapping) of BIST circuit 160(1)-160(B) activations to maximize testing speed. The temperature-aware BIST control system 162 can also be configured to dynamically obtain updated temperature information from the thermal manager circuits 164(1)-164(T) on an ongoing basis during a test mode to be able to dynamically selectively control (e.g., increase and decrease) the number of BIST circuits 160(1)-160(B) activated during the same time.

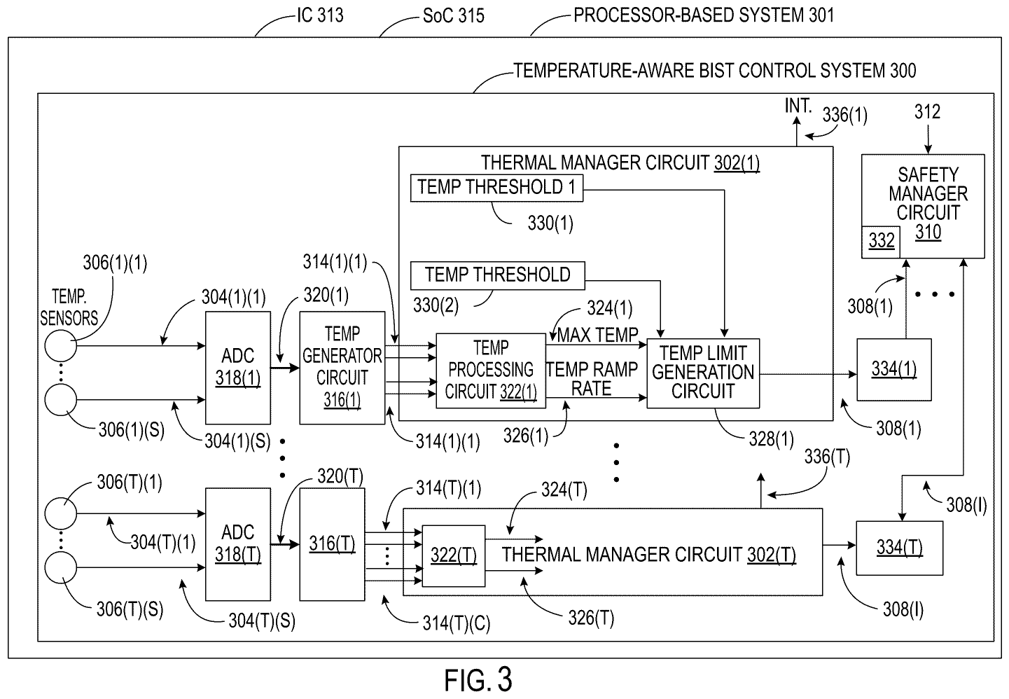

FIG. 3 is a block diagram of an exemplary temperature-aware BIST control system 300 that can be provided as the temperature-aware BIST control system 162 in a processor-based system 301, such as the processor-based system 100 in FIG. 1. As shown in FIG. 3, the temperature-aware BIST control system 300 includes a plurality of thermal manager circuits 302(1)-302(T) each configured to receive a sensed temperature (as temperature information 304(1)(1)-304(1)(S)-304(T)(1)-304(T)(S)) from its respective one or more interfaced temperature sensors 306(1)(1)-306(1)(S)-306(T)(1)-306(T)(S) to then generate a respective temperature limit indicator 308(1)-308(I) indicating if the sensed temperature is within one or more defined thermal limits and/or temperature change rates. Any of the thermal manager circuits 302(1)-302(T) can be provided as any of the thermal manager circuits 164(1)-164(T) in the processor-based system 100 in FIGS. 1 and 2. Also, as shown in FIG. 3, the temperature-aware BIST control system 300 includes a safety manager circuit 310. The safety manager circuit 310 could be included in a SAIL subsystem in a processor-based system, such as the SAIL subsystem 136 in the processor-based system 100 in FIG. 1. As discussed in more detail below, the safety manager circuit 310 is configured to receive the temperature limit indicators 308(1)-308(I) from the thermal manager circuits 302(1)-302(T). In response to a test mode, such as by receiving a test mode indicator 312 indicating a test mode (e.g., in response to an associated processor-based system performing a boot-up operation or entering a safe mode), the safety manager circuit 310 is configured to selectively control activation of an assigned BIST circuit, such as the BIST circuits 160(1)-160(B) in the processor-based system 100 in FIG. 1, based on the respective temperature limit indicators 308(1)-308(I), to maintain a temperature limit within its assigned computing device or die area.

For example, if a given temperature limit indicator 308(1)-308(I) for a respective thermal manager circuit 302(1)-302(T) indicates a temperature greater than a defined maximum temperature threshold, the safety manager circuit 310 can be configured to control and reduce the number of BIST circuits activated during the same time in a test mode to test an assigned computing device with the thermal manager circuit 302(1)-302(T) to maintain a temperature limit. As another example, if a given temperature limit indicator 308(1)-308(I) for a respective thermal manager circuit 302(1)-302(T) indicates a temperature less than a defined maximum temperature threshold, the safety manager circuit 310 can be configured to control and increase the number of BIST circuits activated in a test mode that test a computing device assigned to the thermal manager circuit 302(1)-302(T) to reduce testing time while still maintaining a desired temperature limit. The safety manager circuit 310 can also be configured to control and increase the number of BIST circuits activated in a test mode for one or more computing devices based a temperature limit indicator 308(1)-308(I) generated by a thermal manager circuit 302(1)-302(T) that is not necessarily assigned to a particular computing device, but as a central temperature limit indicator for a die area in an IC 313 (e.g., a SoC 315) (which could be the IC 104 or SoC 102 in FIG. 1) in which the temperature-aware BIST control system 300 is included. The safety manager circuit 310 can also be configured to control and increase the number of BIST circuits (e.g., BIST circuits 160(1)-160(B) in FIG. 1) activated in a test mode for one or more computing devices based on a combination of temperature information in the temperature limit indicators 308(1)-308(I) generated by the thermal manager circuits 302(1)-302(T).

With continuing reference to FIG. 3, more exemplary detail of the thermal manager circuits 302(1)-302(T) in the temperature-aware BIST control system 300 will now be described. In this regard, as shown in FIG. 3, the thermal manager circuits 302(1)-302(T) are each configured to receive one or more temperatures 314(1)(1)-314(1) (C)-314(T)(1)-314(T)(C) as a number that indicates temperature in Celsius from a temperature generator circuit 316(1)-316(T). For example, the temperature generator circuits 316(1)-316(T) may each receive multiple temperatures 314(1)(1)-314(1)(T)-314(T)(1)-314(T)(C) for different components (e.g., processor cores) from multiple temperature sensors 306(1)(1)-306(1)(S)-306(T)(1)-306(T)(S). An analog-to-digital (ADC) circuit 318(1)-318(T) may convert the respective temperature information 304(1) (1)-304(1)(S)-304(T)(1)-304(T)(S) from an analog signal generated by analog temperature sensors 306(1)(1)-306(1)(T)-306(T)(1)-306(T)(C) into digital temperature information 320(1)-320(T) that is then converted into the temperatures 314(1)(1)-314(1) (C)-314(T)(1)-314(T)(C) provided to the respective thermal manager circuits 302(1)-302(T). Each thermal manager circuit 302(1)-302(T) includes a temperature processing circuit 322(1)-322(T) that is configured to receive the respective temperatures 314(1)(1)-314(1)(C)-314(T)(1)-314(T)(C) and convert the received respective temperatures 314(1)(1)-314(1)(C)-314(T)(1)-314(T)(C) into a maximum temperature 324(1)-324(T) and/or temperature change rate 326(1)-326(T). The maximum temperature 324(1)-324(T) is the highest or maximum of the respective individual temperatures 314(1)(1)-314(1)(C)-314(T)(1)-314(T)(C). The temperature change rates 326(1)-326(T) are an indicator of the change in temperature as a function of time (i.e., a first derivative of the respective maximum temperature 324(1)-324(T)).

More exemplary detail of the thermal manager circuit 302(1) in the temperature-aware BIST control system 300 in FIG. 3 will now be discussed. However, note that the same exemplary detail can also be applicable to the other thermal manager circuits 302(2)-302(T) in the temperature-aware BIST control system 300 in FIG. 3.

In this regard, as shown in FIG. 3, the thermal manager circuit 302(1) also includes a temperature limit generation circuit 328(1) that receives the maximum temperature 324(1) and/or temperature change rate 326(1) generated by the temperature processing circuit 322(1). The temperature limit generation circuit 328(1) is configured to compare the maximum temperature 324(1) and/or temperature change rate 326(1) to one or more temperature thresholds. In this example, the temperature limit generation circuit 328(1) is configured to compare the maximum temperature 324(1) and/or temperature change rate 326(1) to two (2) temperature thresholds: a lower temperature threshold 330(1) and a higher temperature threshold 330(2). Note that the thermal manager circuits 302(1)-302(T) could each have the same temperature thresholds 330(1), 330(2) or different temperature thresholds or any combination thereof. The temperature limit generation circuit 328(1) is configured to generate the temperature limit indicator 308(1) that is used by the safety manager circuit 310 to control the number of BIST circuits (e.g., the BIST circuits 160(1)-160(B) in FIG. 1) activated during the same time that are assigned to the thermal manager circuit 302(1). For example, if the temperature limit generation circuit 328(1) determines that the maximum temperature 324(1) and/or the temperature change rate 326(1) are below the lower temperature threshold 330(1), the temperature limit generation circuit 328(1) can be configured to generate the temperature limit indicator 308(1) that indicates a lower temperature limit indicator. For example, the lower temperature threshold 330(1) could be fifty (50) degrees Celsius as a non-limiting example. As another example, the lower temperature threshold 330(1) could be a ten (10) degrees Celsius change per millisecond (ms) as a non-limiting example. In these instances, the safety manager circuit 310 may be configured to implement a BIST control policy 332 that causes all of the BIST circuits (e.g., the BIST circuits 160(1)-160(B) in FIG. 1) assigned to the thermal manager circuit 302(1) to be activated in a test mode during the same time to minimize testing time, since the temperature limit indicator 308(1) indicates the lower temperature limit indicator that may allow all the of the BIST circuits to operate during the same time without exceeding the temperature limit of the higher temperature threshold 330(2).

In another example, if the temperature limit generation circuit 328(1) determines that the maximum temperature 324(1) and/or the temperature change rate 326(1) are above the lower temperature threshold 330(1), but below the higher temperature threshold 330(2), the temperature limit generation circuit 328(1) can be configured to generate the temperature limit indicator 308(1) that indicates an intermediate temperature limit indicator. For example, the higher temperature threshold 330(2) could be eighty-five (85) degrees Celsius as a non-limiting example. As another example, the higher temperature threshold 330(2) could be ten (10) degrees Celsius change per two hundred (200) microseconds (μs). In this instance, the safety manager circuit 310 may be configured to implement the BIST control policy 332 that calls for activating more than one (1) BIST circuit (e.g., the BIST circuits 160(1)-160(B) in FIG. 1) assigned to the thermal manager circuit 302(1), but less than all the BIST circuits assigned to the thermal manager circuit 302(1), since the temperature limit indicator 308(1) indicates the intermediate temperature limit indicator that may allow more than one (1), but less than all of the BIST circuits to operate during the same time without exceeding the temperature limit of the higher temperature threshold 330(2).

In another example, if the temperature limit generation circuit 328(1) determines that the maximum temperature 324(1) and/or the temperature change rate 326(1) are above the higher temperature threshold 330(2), the temperature limit generation circuit 328(1) can be configured to generate the temperature limit indicator 308(1) that indicates a higher temperature limit indicator. In this instance, the safety manager circuit 310 may be configured to implement the BIST control policy 332 that calls for only one (1) of the BIST circuits assigned to the thermal manager circuit 302(1) to be activated during the same time to maintain the desired temperature limit.

In this manner, the temperature-aware BIST control system 300 and its safety manager circuit 310 are configured to control the number of BIST circuits (e.g., the BIST circuits 160(1)-160(B) in FIG. 1) activated during the same time in a test mode to maintain the desired temperature limit. The thermal manager circuit 302(1) can also be configured to continuously generate the temperature limit indicator 308(1) based on changing temperature conditions. The temperature processing circuit 322(1) can continuously and dynamically generate the maximum temperature 324(1) and/or the temperature change rate 326(2). The temperature limit generation circuit 328(1) can continuously and dynamically generate the temperature limit indicator 308(1) based on comparing the temperature thresholds 330(1), 330(2) to the maximum temperature 324(1) and/or the temperature change rate 326(2). For example, if the safety manager circuit 310 implements the BIST control policy 332 based on the temperature limit indicator 308(1) being the higher temperature limit indicator, the temperature may have been subsequently reduced. In this regard, the temperature limit indicator 308(1) may subsequently indicate an intermediate or lower temperature limit indicator, in which case the safety manager circuit 310 can continue to implement the BIST control policy 332 to change the control of the number of assigned BIST circuits activated during the same time to minimize testing time while maintaining the desired temperature limit(s).

Note that the temperature thresholds 330(1), 330(2) can be absolute temperatures for use in comparing to the maximum temperature 324(1). The temperature thresholds 330(1), 330(2) can also be temperature change rates for use in comparing to the temperature change rate 326(1). The temperature thresholds 330(1), 330(2) can be programmable and be programmed by the respective thermal manager circuits 302(1)-302(T), including dynamically during run time, if desired. For example, the CPU 106 may be configured to program or instruct the thermal manager circuits 302(1)-302(T) to program the lower temperature threshold 330(1).

As other examples, the safety manager circuit 310 could be configured to periodically and systematically poll the temperature limit indicators 308(1)-308(I) from respective temperature limit indicator registers 334(1)-334(T) in which the respective thermal manager circuits 302(1)-302(T) store their respective generated temperature limit indicators 308(1)-308(I). As another example, the safety manager circuit 310 could be interrupt driven to be interrupted to execute an interrupt service routing (ISR) to access the temperature limit indicators 308(1)-308(I) from the respective temperature limit indicator registers 334(1)-334(T). For example, the thermal manager circuits 302(1)-302(T) could each be configured to generate an interrupt indicator 336(1)-336(T) when a new temperature limit indicator 308(1)-308(I) is generated to be stored in the respective temperature limit indicator register 334(1)-334(T).

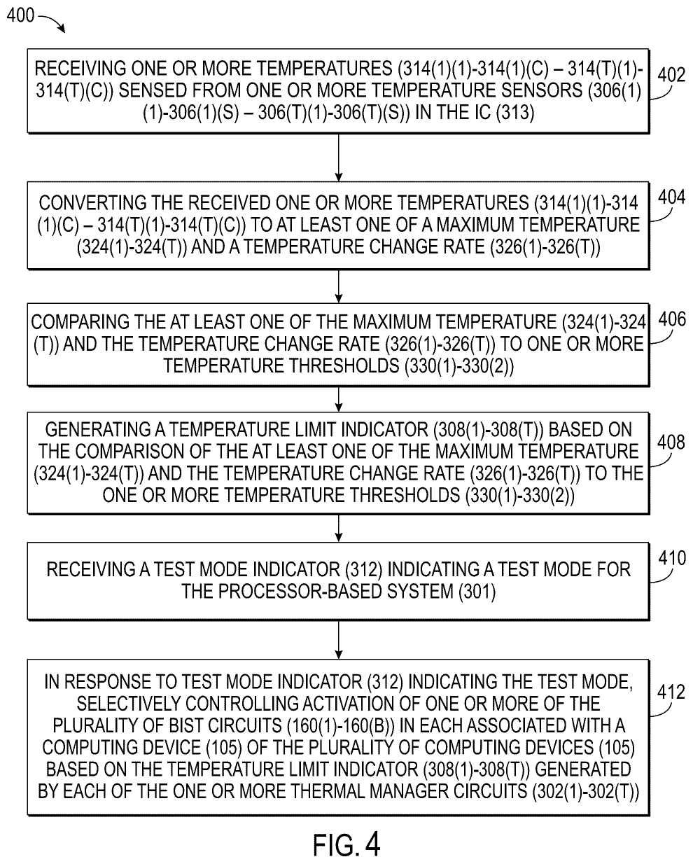

FIG. 4 is flowchart illustrating an exemplary process 400 of a temperature-aware BIST control system for controlling activation of a BIST circuit in a subsystem or component in the processor-based system, based on applying a BIST policy to the temperature limit indicator generated by a thermal manager circuit(s). The process 400 in FIG. 4 is described with regard to the temperature-aware BIST control system 300 in FIG. 3, but such is not limiting and the process 400 could also be performed by the temperature-aware BIST control system 162 in FIG. 1.

In this regard, as shown in FIG. 4, a first step of the process 400 can be one or more of the thermal manager circuits 302(1)-302(T) each receiving one or more temperatures 314(1)(1)-314(1)(C)-314(T)(1)-314(T)(C) sensed from one or more temperature sensors 306(1)(1)-306(1)(S)-306(T)(1)-306(T)(S) in the IC 313 (block 402 in FIG. 4). A next step in the process 400 can be one or more thermal manager circuits 302(1)-302(T) converting the received one or more temperatures 314(1)(1)-314(1)(C)-314(T)(1)-314(T)(C) to at least one of a maximum temperature 324(1)-324(T) and a temperature change rate 326(1)-326(T) (block 404 in FIG. 4). This step may be performed by a temperature processing circuit 322(1)-322(T) in one or more of the thermal manager circuits 302(1)-302(T). A next step in the process 400 can be for the one or more thermal manager circuits 302(1)-320(T) to compare the at least one of the maximum temperature 324(1)-324(T) and the temperature change rate 326(1)-326(T) to one or more temperature thresholds 330(1)-330(2) (block 406 in FIG. 4). This step may be performed by a temperature limit generation circuit 328(1)-328(T) in one or more of the thermal manager circuits 302(1)-302(T). A next step in the process can be the one or more thermal manager circuits 302(1)-320(T) generating a temperature limit indicator 308(1)-308(T) based on the comparison of the at least one of the maximum temperature 324(1)-324(T) and the temperature change rate 326(1)-326(T) to the one or more temperature thresholds 330(1)-330(2) (block 408 in FIG. 4). This step may be performed by a temperature limit generation circuit 328(1)-328(T) in the one or more of the thermal manager circuits 302(1)-302(T). A next step in the process 400 can the safety manager circuit 310 receiving a test mode indicator 312 indicating a test mode for the processor-based system 301 (block 410 in FIG. 4). In response to test mode indicator 312 indicating the test mode, a next step in the process 400 can be the safety manager circuit 310 selectively controlling activation of one or more of the plurality of BIST circuits 160(1)-160(B) associated with each of the plurality of computing devices 105 based on the temperature limit indicator 308(1)-308(T) generated by each of the one or more thermal manager circuits 302(1)-302(T) (block 412 in FIG. 4).

A temperature-aware BIST control system, such as the temperature-aware BIST control systems 162, 300 in FIGS. 1 and 3, can include thermal manager circuits like the thermal manager circuits 164(1)-164(T), 302(1)-302(T) in FIGS. 1 and 3, that are local thermal manager circuits. A local thermal manager circuit is a thermal manager circuit that is assigned to a particular assigned computing device(s), such as the computing devices 105 in the processor-based system 100 in FIG. 1, to be able to sense temperature information about the assigned computing device. For example, a local thermal manager circuit is a thermal manger circuit like the thermal manager circuits 302(1)-302(T) in FIG. 3, but specifically configured to interface with one or more temperature sensors that are either included in or co-located in proximity to an assigned computing device. In this manner, the local thermal manager circuit receives temperature information of or the environment of its assigned computing device in particular to be able to have knowledge of the temperature of the assigned computing device. In this manner, as discussed in more detail below, a safety manager circuit in the temperature-aware BIST control system, like the safety manager circuit 310 in FIG. 3, can apply a local BIST control policy to a local temperature limit indicator generated by the local thermal manager circuit to implement decisions on how to control a BIST circuit associated with the computing device and/or to control the number of BIST circuits in the processor-based system that are activated during the same time to manage temperature limits.

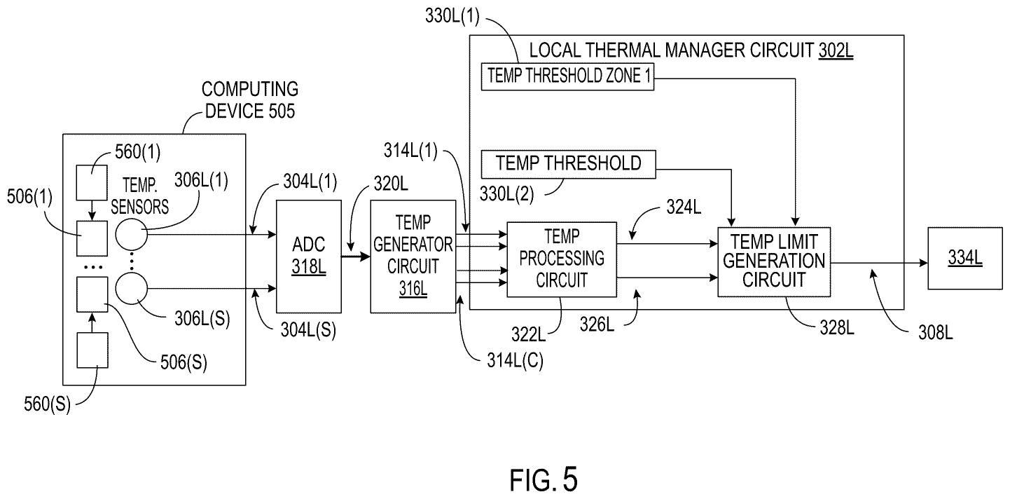

In this regard, FIG. 5 is a block diagram of an exemplary local thermal manager circuit 302L that could be provided in the temperature-aware BIST control systems 162, 300 in FIGS. 1 and 3, and could be any of the thermal manager circuits 302(1)-302(T) in FIG. 3. The local thermal manager circuit 302L is similar to the thermal manager circuits 302(1)-302(T) described above with regard to FIG. 3. The local thermal manager circuit 302L is assigned to a particular computing device, such as the computing devices 105 in the processor-based system 100 in FIG. 1, to be able to process temperature information regarding the assigned computing device. The local thermal manager circuit 302L is configured to generate a local temperature limit indicator 308L based on the temperature information regarding its assigned computing device that can be accessed by a safety manager circuit, such as the safety manager circuit 310 in FIG. 3, to control a BIST circuit associated with a computing device assigned to the local thermal manager circuit 302L. Note that a temperature-aware BIST control system can include a plurality of the local thermal manager circuits 302L that are each assigned to a different computing device in a processor-based system 100, such as the processor-based system 100 in FIG. 1.

As shown in FIG. 5, the local thermal manager circuit 302L is configured to receive one or more local temperatures 314L(1)-314L(C) as a number that indicates temperature in Celsius from a temperature generator circuit 316L. For example, the temperature generator circuit 316L may receive multiple local temperatures 314L(1)-314L(C) for different processor cores 506(1)-506(S) of an assigned processor 505 as a computing device (e.g., the CPU 106, ISP 108, VPU 110, GPU 112, DSPs 114 in FIG. 1), wherein each local temperature 314L(1)-314L(C) is an indication of the current temperature of the respective processor core 506(1)-506(S). A local ADC circuit 318L may convert the respective local temperature 314L(1)-314L(C) from an analog signal generated by analog local temperature sensors 306L(1)-306L(S) each associated with a processor core 506(1)-506(S) into local digital temperature information 320L that is then converted into the local temperatures 314L(1)-314L(C) provided to the local thermal manager circuit 302L. The local thermal manager circuit 302L includes a local temperature processing circuit 322L that is configured to receive the respective local temperatures 314L(1)-314L(C) and convert the received respective temperatures 314L(1)-314L(C) into a local maximum temperature 324L and/or a local temperature change rate 326L. The local maximum temperature 324L is the highest or maximum of the respective individual local temperatures 314L(1)-314L(C). The local temperature change rate 326L is an indicator of the change in temperature as a function of time (i.e., a first derivative of the respective local maximum temperature 324L).

With continuing reference to FIG. 5, the local thermal manager circuit 302L also includes a local temperature limit generation circuit 328L that receives the local maximum temperature 324L and/or local temperature change rate 326L generated by the local temperature processing circuit 322L. The local temperature limit generation circuit 328L is configured to compare the local maximum temperature 324L and/or local temperature change rate 326L to one or more local temperature thresholds. In this example, the local temperature limit generation circuit 328L is configured to compare the local maximum temperature 324L and/or local temperature change rate 326L to two (2) temperature thresholds: a local lower temperature threshold 330L(1) and a local higher temperature threshold 330L(2). The local temperature thresholds 330L(1), 330L(2) can be absolute temperatures for use in comparing to the local maximum temperature 324L. The local temperature thresholds 330L(1), 330L(2) can also be local temperature change rates for use in comparing to the local temperature change rate 326L. The local lower temperature threshold 330L(1) and a local higher temperature threshold 330L(2) could be set to the same values or different values than the temperature threshold 330(1), 330(2) in FIG. 3. The local lower temperature threshold 330L(1) and the local higher temperature threshold 330L(2) could also be programmable, including dynamically, by a respective local thermal manager circuit 302L and/or through the CPU 104, like previous described for the thermal manager circuits 302(1)-302(T) in FIG. 3.

With continuing reference to FIG. 5, the local temperature limit generation circuit 328L is configured to generate the local temperature limit indicator 308L that is used by the safety manager circuit 310 to control logic BIST (LBIST) circuits 560(1)-560(S) associated with the processor 505 in this example according to a local BIST control policy. In this example of the computing device associated with the local thermal manager circuit 302L being the processor 505 with its processor cores 506(1)-506(S), the LBIST circuits 560(1)-560(S) are provided in the processor 505 that are configured to perform logic testing of their respective assigned processor cores 506(1)-506(S). This in this example, a safety manager circuit can be configured to use the local temperature limit indicator 308L generated by the local thermal manager circuit 302L to selectively control the number of LBIST circuits 560(1)-560(S) activated during the same time to test the processor cores 506(1)-506(S) according to a local BIST control policy.

Note that as another example, the local thermal manager circuit 302L could be assigned to a memory system, such as the memory system 120 in FIG. 1, to generate the local temperature limit indicator 308L indicative of temperature and/or temperature change rate in the memory system being within a designed temperature threshold. In this example, the safety manager circuit could be configured to use the local temperature limit indicator 308L generated by the local thermal manager circuit 302L to selectively control the number of memory BIST (MBIST) circuits activated during the same time to test different components of the memory system 120 according to a local BIST control policy. For example, as such in FIG. 5, what is shown as processor cores 506(1)-506(S) could be memory components or circuits, and the LBIST circuits 560(1)-560(S) could be MBIST circuits each configured to test a respective memory component or circuit.

With continuing reference to FIG. 5, as an example, if the local temperature limit generation circuit 328L in the local thermal manager circuit 302L determines that the local maximum temperature 324L and/or the local temperature change rate 326L are below the local lower temperature threshold 330L(1), the local temperature limit generation circuit 328L can be configured to generate the local temperature limit indicator 308L that indicates a local lower temperature limit indicator. For example, the lower temperature threshold may be fifty (50) degrees Celsius as a non-limiting example. In another example, if the local temperature limit generation circuit 328L in the local thermal manager circuit 302L determines that the local maximum temperature 324L and/or the local temperature change rate 326L are above the local lower temperature threshold 330L(1), but below the local higher temperature threshold 330L(2), the local temperature limit generation circuit 328L can be configured to generate the local temperature limit indicator 308L that indicates a local intermediate temperature limit indicator. For example, the higher temperature threshold may be eighty-five (85) degrees Celsius as a non-limiting example. In another example, if the local temperature limit generation circuit 328L in the local thermal manager circuit 302L determines that the local maximum temperature 324L and/or the local temperature change rate 326L are above the local higher temperature threshold 330L(2), the local temperature limit generation circuit 328L can be configured to generate the local temperature limit indicator 308L that indicates a local higher temperature limit indicator.

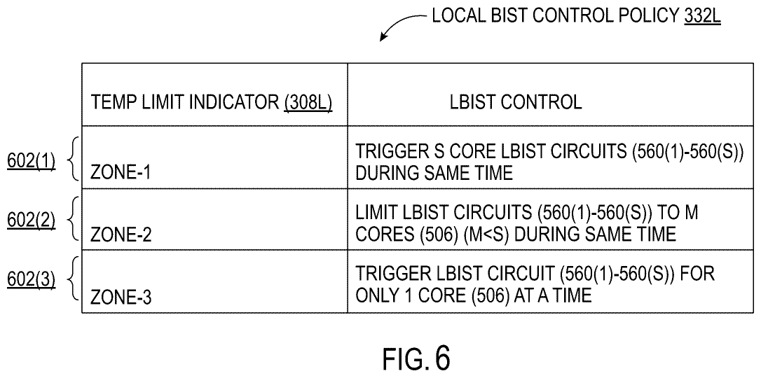

FIG. 6 is a chart illustrating an exemplary local BIST control policy 332L that can be used by the safety manager circuit, such as the safety manager circuit 310 in FIG. 3, to selectively control activation of BIST circuits in the processor 505 assigned to a local thermal manager circuit 302L in FIG. 5, based on the local temperature limit indicator 308L generated by the local thermal manager circuit 302L in FIG. 5. In this regard, as shown in FIG. 6, the local BIST control policy 332L in this example includes three (3) local BIST control policies 602(1)-602(3) that are each respectively associated with local lower, intermediate, and higher temperature limit indicators that can be indicated by the local temperature limit indicator 308L generated by the local thermal manager circuit 302L in FIG. 5. In this example local BIST control policy 332L, as shown in FIG. 5, a local temperature limit indicator 308L indicating a local lower temperature limit indicator (e.g., Zone 1) is associated with a first local BIST control policy 602(1). In this example, the safety manager circuit is configured to apply the first local BIST control policy 602(1) in response to the local temperature limit indicator 308L indicating a local lower temperature limit indicator to activate all of the LBIST circuits 560(1)-560(B) in the processor 505 to test each of the processor cores 506(1)-506(S) in FIG. 5 during the same time to maintain the temperature limit in the processor 505. However, as shown in FIG. 6, in response to the local temperature limit indicator 308L indicating a local intermediate temperature limit indicator, the safety manager circuit is configured to apply a second local BIST control policy 602(2) to activate more than one (1), but less than all of the LBIST circuits 560(1)-560(B) in the processor 505 to test each of the processor cores 506(1)-506(S) in FIG. 5 during the same time to maintain the temperature limit in the processor 505. As also shown in FIG. 6, in response to the local temperature limit indicator 308L indicating a local higher temperature limit indicator, the safety manager circuit is configured to apply a third local BIST control policy 602(3) to only one (1) of the LBIST circuits 560(1)-560(B) in the processor 505 at a given time to test only one processor cores 506(1)-506(S) at a given time to maintain the temperature limit in the processor 505.

In this manner, the local thermal manager circuit 302L in FIG. 5 facilitates a safety manager circuit, like the safety manager circuit 310 in FIG. 3, controlling the number of BIST circuits (e.g., LBIST circuits 560(1)-560(S) in FIG. 5) activated during the same time in a test mode to maintain the desired temperature limit of a computing device assigned to the local thermal manager circuit 302L. The local thermal manager circuit 302L in FIG. 5 can also be configured to continuously generate the local temperature limit indicator 308L based on changing temperature conditions. The local temperature processing circuit 322L can continuously and dynamically generate the local maximum temperature 324L and/or the local temperature change rate 326L. The local temperature limit generation circuit 328L can continuously and dynamically generate the temperature limit indicator 308L based on comparing the local temperature thresholds 330L(1), 330L(2) to the local maximum temperature 324L and/or the local temperature change rate 326L. For example, if a safety manager circuit implements the local BIST control policy 332L in FIG. 6 based on the local temperature limit indicator 308L being the local higher temperature limit indicator, the temperature in the processor 505 may have subsequently reduced. In this regard, the local temperature limit indicator 308L may subsequently indicate a local intermediate or lower temperature limit indicator, in which case a safety manager circuit can continue to implement the local BIST control policy 332L to change the control of the number of LBIST circuits 560(1)-560(S) activated in the processor 505 during the same time to minimize testing time of the processor 505 while maintaining the desired temperature limit of the processor 505.

A temperature-aware BIST control system, such as the temperature-aware BIST control systems 162, 300 in FIGS. 1 and 3, can also include a thermal manager circuit like the thermal manager circuits 164(1)-164(T), 302(1)-302(T) in FIGS. 1 and 3, that is a central thermal manager circuit. A central thermal manager circuit is a thermal manager circuit that is not assigned to a particular computing device(s), such as the computing devices 105 in the processor-based system 100 in FIG. 1, but an area of the die of the processor-based system in which the central thermal manager circuit is located. The central thermal manager circuit is configured to sense temperature information about the die and its IC that includes the temperature-aware BIST control system and the BIST circuits associated with different computing devices in the processor-based system. In this manner, even if the temperature of the computing devices that can be analyzed by local thermal manager circuits, like the local thermal manager circuit 302L in FIG. 5, does not indicate temperatures outside of desired temperature limits, the central thermal manager circuit is also able to analyze if any environmental temperatures are outside of desired temperature limits, because such could also affect the operation and circuit failures of the processor-based system. In this manner, as discussed in more detail below, a safety manager circuit in the temperature-aware BIST control system, like the safety manager circuit 310 in FIG. 3, can apply a central BIST control policy to a central temperature limit indicator generated by the central thermal manager circuit to implement decisions on how to control BIST circuits associated with computing devices in the processor-based system that are activated during the same time to manage temperature limits of the IC that includes the BIST circuits and its associated computing devices.

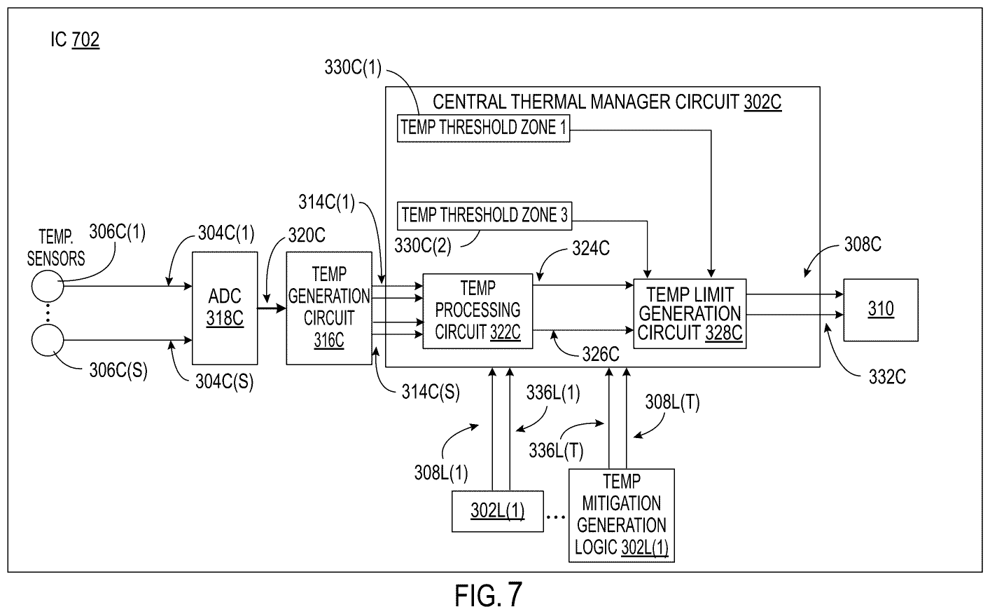

In this regard, FIG. 7 is a block diagram of an exemplary central thermal manager circuit 302C that could be provided in the temperature-aware BIST control systems 162, 300 in FIGS. 1 and 3, and could be any of the thermal manager circuits 302(1)-302(T) in FIG. 3. The central thermal manager circuit 302C is similar to the thermal manager circuits 302(1)-302(T) described above with regard to FIG. 3. The central thermal manager circuit 302C is located in a particular environmental area of a die in an IC 702, which could be the IC 104 or its SoC 102 in the processor-based system 100 in FIG. 1, that includes a processor-based system. The central thermal manager circuit 302C is configured to generate a central temperature limit indicator 308C based on the temperature information regarding the environment of the IC 702 in which interfaced central temperature sensors 306C(1)-306C(S) are located in an IC that can be accessed by a safety manager circuit, such as the safety manager circuit 310 in FIG. 3, to control the BIST circuits (e.g., the BIST circuits 160(1)-160(B) in FIG. 1) activated during the same time.

As shown in FIG. 7, the central thermal manager circuit 302C is configured to receive one or more central temperatures 314C(1)-314C(S) as a number that indicates temperature in Celsius from a temperature generator circuit 316C. For example, the temperature generator circuit 316C may receive multiple central temperatures 314C(1)-314C(S) from central temperature sensors 306C(1)-306C(S) located in different areas of the IC 702 such that each central temperature 314C(1)-314C(S) is an indication of the current temperature in such area of the IC 702. A central ADC circuit 318C may convert respective central temperature information 304C(1)-304C(S) from an analog signal generated by the central analog temperature sensors 306C(1)-306C(S) each associated with a processor core 506(1)-506(S) into a central digital temperature information 320C that is then converted into the central temperatures 314C(1)-314C(S) provided to the central thermal manager circuit 302C. The central thermal manager circuit 302C includes a central temperature processing circuit 322C that is configured to receive the respective central temperatures 314C(1)-314C(S) and convert the received respective central temperatures 314C(1)-314C(S) into a central maximum temperature 324C and/or a central temperature change rate 326C. The central maximum temperature 324C is the highest or maximum of the respective individual central temperatures 314C(1)-314C(S). The central temperature change rate 326C is an indicator of the change in temperature as a function of time (i.e., a first derivative of the respective central maximum temperature 324C).

With continuing reference to FIG. 7, the central thermal manager circuit 302C also includes a central temperature limit generation circuit 328C that receives the central maximum temperature 324C and/or the central temperature change rate 326C generated by the central temperature processing circuit 322C. The central temperature limit generation circuit 328C is configured to compare the central maximum temperature 324C and/or the central temperature change rate 326C to one or more central temperature thresholds. In this example, the central temperature limit generation circuit 328C is configured to compare the central maximum temperature 324C and/or the central temperature change rate 326C to two (2) temperature thresholds: a central lower temperature threshold 330C(1) and a central higher temperature threshold 330C(2). The central temperature thresholds 330C(1), 330C(2) can be absolute temperatures for use in comparing to the central maximum temperature 324C. The central temperature thresholds 330C(1), 330C(2) can also be central temperature change rates for use in comparing to the central temperature change rate 326C. The central lower temperature threshold 330C(1) and a central higher temperature threshold 330C(2) could be set to the same values or different values than the temperature threshold 330(1), 330(2) in FIG. 3. The central lower temperature threshold 330C(1) and central higher temperature threshold 330C(2) could also be programmable, including dynamically, by the central thermal manager circuit 302C and/or through the CPU 104, like previous described for the thermal manager circuits 302(1)-302(T) in FIG. 3. The central temperature limit generation circuit 328C is configured to generate the central temperature limit indicator 308C that is used by a safety manager circuit, such as the safety manager circuit 310 in FIG. 3, to control activation of BIST circuits in a test mode, such as the BIST circuits 160(1)-160(B) in the processor-based system 100 in FIG. 1, according to a central BIST control policy.

With continuing reference to FIG. 7, as an example, if the central temperature limit generation circuit 328C in the central thermal manager circuit 302C determines that the central maximum temperature 324C and/or the central temperature change rate 326C are below the central lower temperature threshold 330C(1), the central temperature limit generation circuit 328C can be configured to generate the central temperature limit indicator 308C that indicates a central lower temperature limit indicator. For example, the lower temperature threshold may be fifty (50) degrees Celsius as a non-limiting example. In another example, if the central temperature limit generation circuit 328C in the central thermal manager circuit 302C determines that the central maximum temperature 324C and/or the central temperature change rate 326C are above the central lower temperature threshold 330C(1), but below the central higher temperature threshold 330C(2), the central temperature limit generation circuit 328C can be configured to generate the central temperature limit indicator 308C that indicates a central intermediate temperature limit indicator. For example, the higher temperature threshold may be eighty-five (85) degrees Celsius as a non-limiting example. In another example, if the central temperature limit generation circuit 328C in the central thermal manager circuit 302C determines that the central maximum temperature 324C and/or the central temperature change rate 326C are above the central higher temperature threshold 330C(2), the central temperature limit generation circuit 328C can be configured to generate the central temperature limit indicator 308C that indicates a central higher temperature limit indicator.

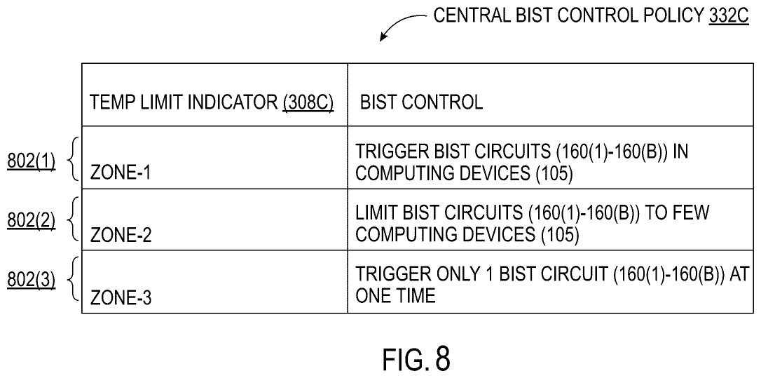

FIG. 8 is a chart illustrating an exemplary central BIST control policy 332C that can be used by the safety manager circuit, such as the safety manager circuit 310 in FIG. 3, to selectively control activation of BIST circuits in a processor-based system, such as the BIST circuits 160(1)-160(B) in the processor-based system 100 in FIG. 1, based on the central temperature limit indicator 308C generated by the central thermal manager circuit 302C in FIG. 7. In this regard, as shown in FIG. 7, the central BIST control policy 332C in this example includes three (3) central BIST control policies 802(1)-802(3) that are each respectively associated with central lower, intermediate, and higher temperature limit indicators that can be indicated by the central temperature limit indicator 308C generated by the central thermal manager circuit 302C in FIG. 7. In this example, as shown in FIG. 7, the central temperature limit indicator 308C indicating a central lower temperature limit indicator (e.g., Zone 1) is associated with a first central BIST control policy 802(1). In this example, as shown in FIG. 8, the safety manager circuit is configured to apply the first central BIST control policy 802(1) in response to the central temperature limit indicator 308C indicating a central lower temperature limit indicator to activate all of the BIST circuits in a processor-based system (e.g., the BIST circuits 160(1-160(B) in FIG. 1) during the same time to maintain temperature limit in the processor-based system. However, as shown in FIG. 8, in response to the central temperature limit indicator 308C indicating a central intermediate temperature limit indicator, the safety manager circuit is configured to apply a second central BIST control policy 802(2) to activate more than one (1), but less than all of the BIST circuits in a processor-based system (e.g., the BIST circuits 160(1)-160(B) in FIG. 1) during the same time to maintain the temperature limit in the processor-based system. As also shown in FIG. 8, in response to the central temperature limit indicator 308C indicating a central higher temperature limit indicator, the safety manager circuit is configured to apply a third local BIST control policy 802(3) to only one (1) BIST circuit in a processor-based system (e.g., the BIST circuits 160(1)-160(B) in FIG. 1) at a given time to maintain the temperature limit in the processor-based system.

In this manner, the central thermal manager circuit 302C in FIG. 7 facilitates a safety manager circuit, like the safety manager circuit 310 in FIG. 3, controlling the number of BIST circuits (e.g., the BIST circuits 160(1)-160(B) in FIG. 1) activated during the same time in a test mode to maintain the desired temperature limit of a processor-based system. The central thermal manager circuit 302C in FIG. 7 can also be configured to continuously generate the central temperature limit indicator 308C based on changing temperature conditions. The central temperature processing circuit 322C can continuously and dynamically generate the central maximum temperature 324C and/or the central temperature change rate 326C. The central temperature limit generation circuit 328C can continuously and dynamically generate the central temperature limit indicator 308C based on comparing the central temperature thresholds 330C(1), 330C(2) to the central maximum temperature 324C and/or the central temperature change rate 326C. For example, if a safety manager circuit implements the central BIST control policy 332C in FIG. 8 based on the central temperature limit indicator 308C being the central higher temperature limit indicator, the temperature in the IC 702 may have subsequently reduced. In this regard, the central temperature limit indicator 308C may subsequently indicate a central intermediate or lower temperature limit indicator, in which case a safety manager circuit can continue to implement the central BIST control policy 332C to change the control of the number of BIST circuits activated in a processor-based system during the same time to minimize testing time of the processor-based system while maintaining the desired temperature limit of the processor-based system.

As also shown in FIG. 7, in this example, the central thermal manager circuit 302C is configured to interface with local thermal manager circuits 302L(1)-302L(T), like the local thermal manager circuit 302L in FIG. 3. The central thermal manager circuit 302C is configured to receive the local temperature limit indicators 308L(1)-308L(T) generated by the respective local thermal manager circuits 302L(1)-302L(T) as well as receive the interrupt indicators 336L(1)-336L(T) generated by the respective local thermal manager circuits 302L(1)-302L(T). The central thermal manager circuit 302C can be configured to aggregate the local temperature limit indicators 308L(1)-308L(T) and the interrupt indicators 336L(1)-336L(T) with the central temperature limit indicator 308C, so that the central temperature limit generation circuit 328C could also generate the central temperature limit indicator 308C not only based on the central maximum temperature 324C and/or the central temperature change rate 326C, but also on the local temperature limit indicators 308L(1)-308L(T). This allows the central thermal manager circuit 302C to generate the central temperature limit indicator 308C that provides information on whether any temperatures and/or temperature changes rates locally and environmentally in an IC of a processor-based system are within desired temperature limits for a safety manager circuit to apply a central BIST control policy, like the central BIST control policy 332C in FIG. 8 for example. However, the safety manager circuit can still apply local BIST control policies, like the local BIST control policy 332L in FIG. 6, to the BIST circuits in the specific computing devices.

A temperature-aware BIST control system can also be provided that includes both local thermal manager circuits, like the local thermal manager circuit 302L in FIG. 5, and a central thermal manager circuit(s), like the central thermal manager circuit 302C in FIG. 7. In this manner, as an example, the temperature-aware BIST control system can control both the activation of a number of BIST circuits associated with different computing devices in a processor-based system during the same time, as well as control the number of circuits or components within a given computing device test during the same time, to manage temperature limits in a test mode.

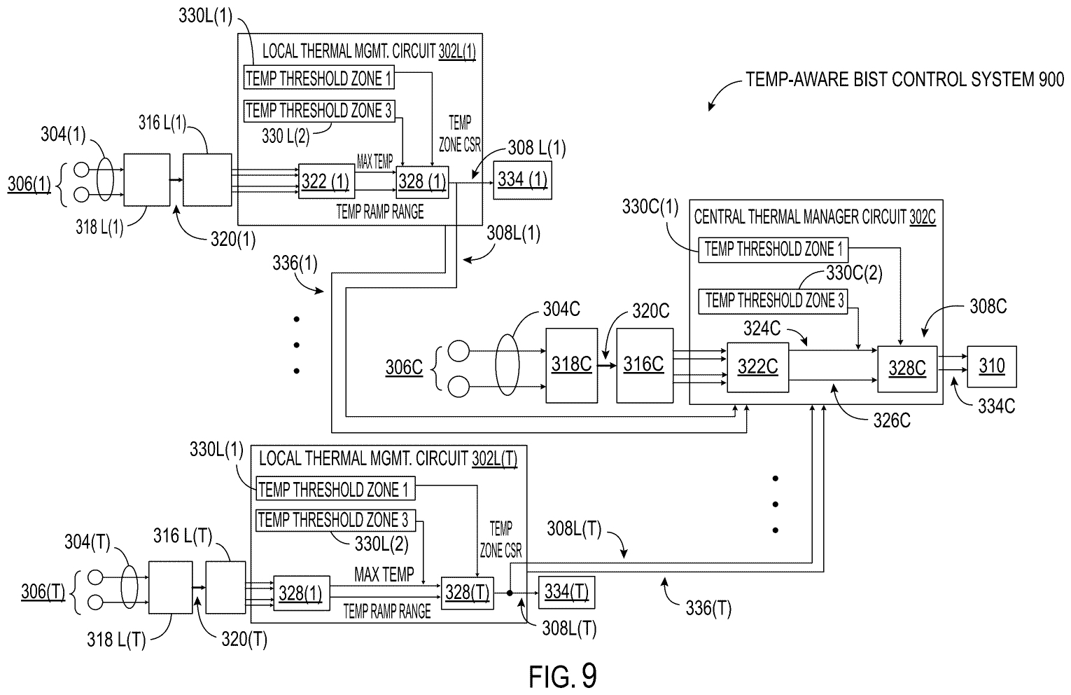

In this regard, FIG. 9 is a block diagram of an exemplary temperature-aware BIST control system 900 that can be provided in a processor-based system, such as the processor-based system 100 in FIG. 1. As shown in FIG. 9, the temperature-aware BIST control system 900 includes a plurality of local thermal manager circuits 302L(1)-302L(T) (e.g., like the local thermal manager circuit 302L in FIG. 3) configured to generate respective local temperature limit indicators 308L(1)-308L(T). The central temperature limit indicator 308C and the local temperature limit indicators 308L(1)-308L(T) are accessible by a safety manager circuit, such as the safety manager circuit 310 in FIG. 3, configured to selectively control the number of BIST circuits (e.g., the BIST circuits 160(1)-160(B) in FIG. 1, LBIST circuits 560(1)-560(S) in FIG. 5) activated during the same time, based on a central BIST control policy and/or a local BIST control policy applied to the respective central temperature limit indicator 308C and local temperature limit indicators 308L(1)-308L(T). The applied local BIST control policy could be the local BIST control policy 332L in FIG. 6. The applied central BIST control policy could be the central BIST control policy 332C in FIG. 8. The previous discussion and description of the thermal manager circuits 302(1)-302(T) in FIG. 3, the local thermal manager circuit 302L in FIG. 5, and the central thermal manager circuit 302C in FIG. 7 is applicable to the temperature-aware BIST control system 900 in FIG. 9.

A temperature-aware BIST control system, such as the temperature-aware BIST control systems 162, 300, 900 in FIGS. 1, 3, 5, 7, and 9, configured to selectively control activation of BIST circuits in a processor-based system during the same time based on applying a BIST control policy(ies) to a temperature limit indicator(s) generated by a thermal manager circuit(s), to minimize staggering of BIST circuit activations to maximize testing speed while at the same time reducing or avoiding circuit failures due to excess temperature, and according to a process including, but not limited to, the exemplary process 400 in FIG. 4, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

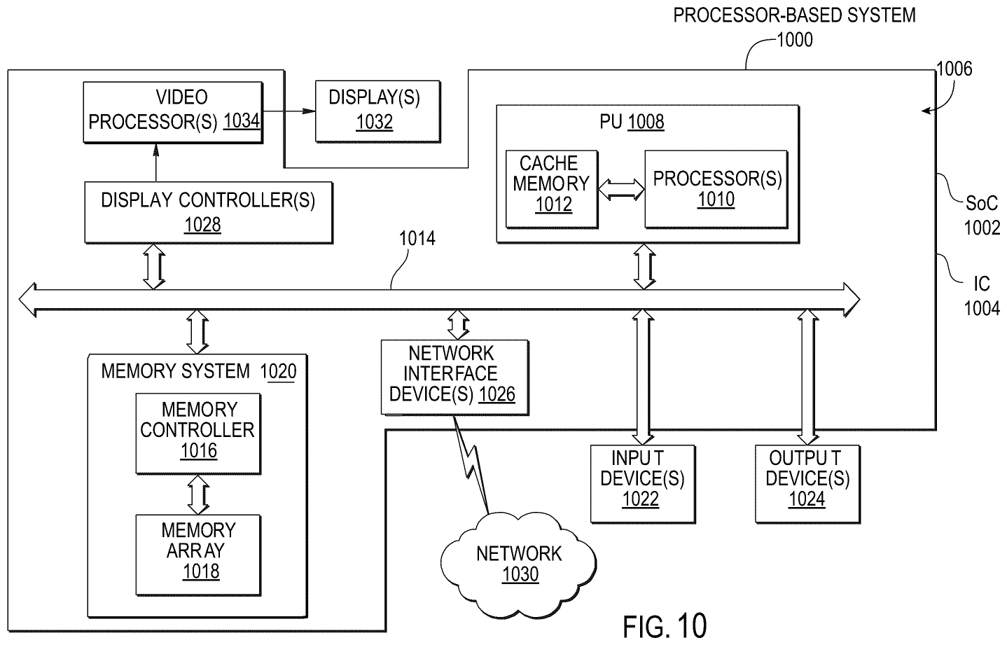

In this regard, FIG. 10 illustrates an example of a processor-based system 1000 included in a SoC 1002 that is provided in an IC 1004, wherein the IC 1004 includes a temperature-aware BIST control system 1006, such as the temperature-aware BIST control systems 162, 300, 900 in FIGS. 1, 3, 5, 7, and 9, configured to selectively control activation of BIST circuits in the processor-based system 1000 during the same time based on applying a BIST control policy(ies) to a temperature limit indicator(s) generated by a thermal manager circuit(s), to minimize staggering of BIST circuit activations to maximize testing speed while at the same time reducing or avoiding circuit failures due to excess temperature, and according to a process including, but not limited to, the exemplary process 400 in FIG. 4, and according to any aspects disclosed herein.

The processor-based system 1000 includes a processing unit (PU) 1008 that includes one or more processors 1010. The PU 1008 may have a shared cache memory 1012 coupled to the PU 1008 for rapid access to temporarily stored data. The processors 1010 are coupled to a system bus 1014 and can intercouple master and slave devices included in the processor-based system 1000. As is well known, the processors 1010 communicate with these other devices by exchanging address, control, and data information over the system bus 1014. For example, the processors 1010 can communicate bus transaction requests to a memory controller 1016, as an example of a slave device. Although not illustrated in FIG. 10, multiple system buses 1014 could be provided, wherein each system bus 1014 constitutes a different fabric. Other master and slave devices can be connected to the system bus 1014. As illustrated in FIG. 10, these devices can include a memory system 1020 that includes the memory controller 1016 and a memory array(s) 1018.

With continuing reference to FIG. 10, the processor-based system 1000 also includes one or more input devices 1022, one or more output devices 1024, one or more network interface devices 1026, and one or more display controllers 1028 as examples. The input device(s) 1022 can include any type of input device, including, but not limited to, input keys, switches, voice processors, etc. The output device(s) 1024 can include any type of output device, including, but not limited to, audio, video, other visual indicators, etc. The network interface device(s) 1026 can be any device configured to allow exchange of data to and from a network 1030. The network 1030 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1030 can be configured to support any type of communications protocol desired.

The processors 1010 may also be configured to access the display controller(s) 1028 over the system bus 1014 to control information sent to one or more displays 1032. The display controller(s) 1028 sends information to the display(s) 1032 to be displayed via one or more video processors 1034, which process the information to be displayed into a format suitable for the display(s) 1032. The display controller(s) 1028 and video processor(s) 1034 can be included in the same or different ICs, or in the same IC containing the PU 1008, as examples. The display(s) 1032 can include any type of display, including, but not limited to, a cathode ray tube (CRT), a liquid crystal display (LCD), a plasma display, a light emitting diode (LED) display, etc.

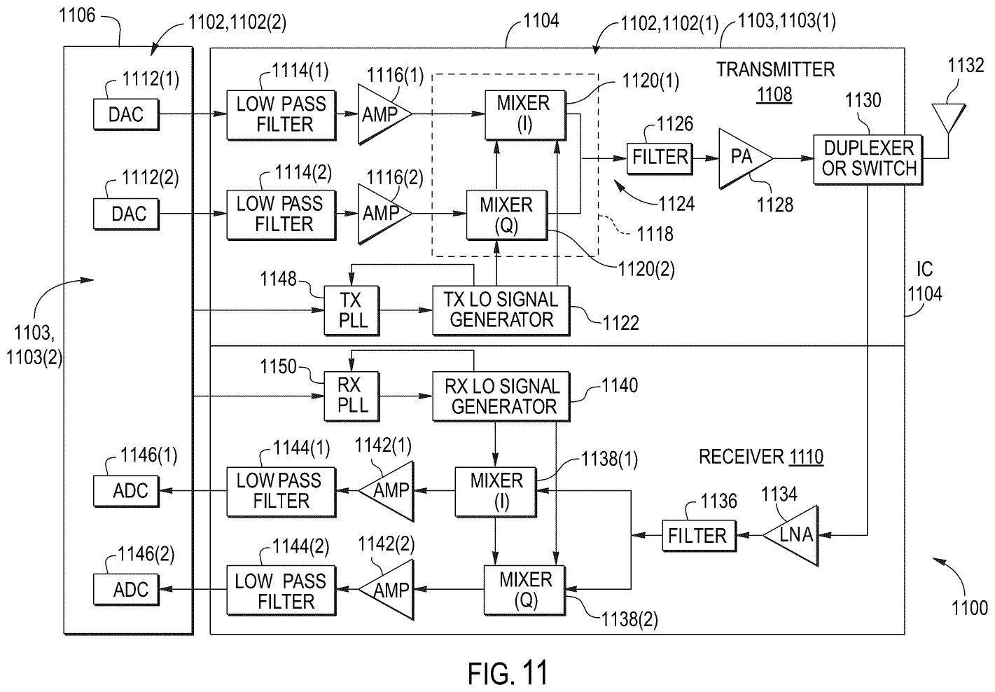

FIG. 11 illustrates an exemplary wireless communications device 1100 that includes radio frequency (RF) components and that can include a processor-based system 1102, 1102(1), 1102(2) that includes a temperature-aware BIST control system 1103, 1103(1), 1103(2), such as the temperature-aware BIST control systems 162, 300, 900 in FIGS. 1, 3, 5, 7, and 9, configured to selectively control activation of BIST circuits in the processor-based system 1102, 1102(1), 1102(2) during the same time based on applying a BIST control policy(ies) to a temperature limit indicator(s) generated by a thermal manager circuit(s), to minimize staggering of BIST circuit activations to maximize testing speed while at the same time reducing or avoiding circuit failures due to excess temperature, and according to a process including, but not limited to, the exemplary process 400 in FIG. 4, and according to any aspects disclosed herein.

As shown in FIG. 11, the wireless communications device 1100 includes a transceiver 1104 and a data processor 1106, each of which may include its processor-based system 1102(1), 1102(2). The transceiver 1104 includes a transmitter 1108 and a receiver 1110 that support bi-directional communications. In general, the wireless communications device 1100 may include any number of transmitters 1108 and/or receivers 1110 for any number of communication systems and frequency bands. All or a portion of the transceiver 1104 may be implemented on one or more analog ICs, RF ICs (RFICs), mixed-signal ICs, etc.

The transmitter 1108 or the receiver 1110 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 1110. In the direct-conversion architecture, a signal is frequency-converted between RF and baseband in one stage. The super-heterodyne and direct-conversion architectures may use different circuit blocks and/or have different requirements. In the wireless communications device 1100 in FIG. 11, the transmitter 1108 and the receiver 1110 are implemented with the direct-conversion architecture.

In the transmit path, the data processor 1106 processes data to be transmitted and provides I and Q analog output signals to the transmitter 1108. In the exemplary wireless communications device 1100, the data processor 1106 includes digital-to-analog converters (DACs) 1112(1), 1112(2) for converting digital signals generated by the data processor 1106 into the I and Q analog output signals, e.g., I and Q output currents, for further processing.

Within the transmitter 1108, lowpass filters 1114(1), 1114(2) filter the I and Q analog output signals, respectively, to remove undesired signals caused by the prior digital-to-analog conversion. Amplifiers (AMPs) 1116(1), 1116(2) amplify the signals from the lowpass filters 1114(1), 1114(2), respectively, and provide I and Q baseband signals. An upconverter 1118 upconverts the I and Q baseband signals with I and Q transmit (TX) local oscillator (LO) signals through mixers 1120(1), 1120(2) from a TX LO signal generator 1122 to provide an upconverted signal 1124. A filter 1126 filters the upconverted signal 1124 to remove undesired signals caused by the frequency up-conversion as well as noise in a receive frequency band. A power amplifier (PA) 1128 amplifies the upconverted signal 1124 from the filter 1126 to obtain the desired output power level and provides a transmit RF signal. The transmit RF signal is routed through a duplexer or switch 1130 and transmitted via an antenna 1132.

In the receive path, the antenna 1132 receives signals transmitted by base stations and provides a received RF signal, which is routed through the duplexer or switch 1130 and provided to a low noise amplifier (LNA) 1134. The duplexer or switch 1130 is designed to operate with a specific receive (RX)-to-TX duplexer frequency separation, such that RX signals are isolated from TX signals. The received RF signal is amplified by the LNA 1134 and filtered by a filter 1136 to obtain a desired RF input signal. Down-conversion mixers 1138(1), 1138(2) mix the output of the filter 1136 with I and Q RX LO signals (i.e., LO_I and LO_Q) from an RX LO signal generator 1140 to generate I and Q baseband signals. The I and Q baseband signals are amplified by AMPs 1142(1), 1142(2) and further filtered by lowpass filters 1144(1), 1144(2) to obtain I and Q analog input signals, which are provided to the data processor 1106. In this example, the data processor 1106 includes ADCs 1146(1), 1146(2) for converting the analog input signals into digital signals to be further processed by the data processor 1106.

In the wireless communications device 1100 of FIG. 11, the TX LO signal generator 1122 generates the I and Q TX LO signals used for frequency up-conversion, while the RX LO signal generator 1140 generates the I and Q RX LO signals used for frequency down-conversion. Each LO signal is a periodic signal with a particular fundamental frequency. A TX phase-locked loop (PLL) circuit 1148 receives timing information from the data processor 1106 and generates a control signal used to adjust the frequency and/or phase of the TX LO signals from the TX LO signal generator 1122. Similarly, an RX PLL circuit 1150 receives timing information from the data processor 1106 and generates a control signal used to adjust the frequency and/or phase of the RX LO signals from the RX LO signal generator 1140.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device or processing unit, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. A processor-based system comprising an integrated circuit (IC), comprising:
   a plurality of computing devices, wherein each computing device of the plurality of computing devices comprises:
      a plurality of built-in self-test (BIST) circuits each associated with a computing device of the plurality of computing devices, each BIST circuit of the plurality of BIST circuits configured to be activated to test its associated computing device; and
      a BIST control system, comprising:
         a safety manager circuit configured to selectively control activation of the BIST circuit of each of the plurality of computing devices; and
         one or more thermal manager circuits each configured to:
         receive one or more temperatures sensed from one or more temperature sensors in the IC;
         convert the received one or more temperatures to at least one of a maximum temperature and a temperature change rate;
         compare the at least one of the maximum temperature and the temperature change rate to one or more temperature thresholds; and
         generate a temperature limit indicator based on the comparison of the at least one of the maximum temperature and the temperature change rate to the one or more temperature thresholds;
         the safety manager circuit configured to:
         receive a test mode indicator indicating a test mode for the processor-based system; and
         in response to the test mode indicator indicating the test mode:
         selectively control the activation of the BIST circuit associated with each of the plurality of computing devices based on the temperature limit indicator generated by each of the one or more thermal manager circuits.
2. The processor-based system of clause 1, wherein:
   each of the one or more thermal manager circuits comprises:
      a temperature processing circuit configured to:
         dynamically receive the one or more temperatures sensed from the one or more temperature sensors in the IC; and
      a temperature limit generation circuit configured to:
         dynamically compare the at least one of the maximum temperature and the temperature change rate to the one or more temperature thresholds; and
         dynamically generate the temperature limit indicator based on the comparison of the at least one of the maximum temperature and the temperature change rate to the one or more temperature thresholds; and
   the safety manager circuit is configured to, in response to the test mode indicator indicating the test mode:
      dynamically selectively control the activation of the BIST circuit in each of the plurality of computing devices based on the temperature limit indicator generated by each of the one or more thermal manager circuits.
3. The processor-based system of clause 2 or 3, wherein the one or more thermal manager circuits are each configured to, in response to the test mode indicator indicating the test mode:
   receive the one or more temperatures sensed from the one or more temperature sensors in the IC;
   convert the received one or more temperatures to the at least one of the maximum temperature and the temperature change rate;
   compare the at least one of the maximum temperature and the temperature change rate to the one or more temperature thresholds; and
   generate the temperature limit indicator based on the comparison of the at least one of the maximum temperature and the temperature change rate to the one or more temperature thresholds.
4. The processor-based system of any of clauses 1-3, wherein in response to the test mode indicator indicating the test mode, the safety manager circuit is further configured to, for each temperature limit indicator generated by each of the one or more thermal manager circuits:
   apply a BIST control policy to the temperature limit indicator to generate a BIST control indicator; and
   selectively control activation of the BIST circuit in each of the plurality of computing devices based on the BIST control indicator.
5. The processor-based system of any of clauses 1-3, wherein:
   the one or more temperature thresholds comprise a first temperature threshold;
   the one or more thermal manager circuits are each configured to:
      compare the at least one of the maximum temperature and the temperature change rate to the first temperature threshold; and
      generate the temperature limit indicator by being configured to:
         generate the temperature limit indicator as a lower temperature limit indicator based on the comparison of the at least one of the maximum temperature and the temperature change rate being less than the first temperature threshold; and
         generate the temperature limit indicator as a higher temperature limit indicator based on the comparison of the at least one of the maximum temperature and the temperature change rate being greater than the first temperature threshold; and
   the safety manager circuit is configured to, in response to test mode indicator indicating the test mode, selectively control activation of the BIST circuit by being configured to:
      activate the BIST circuit in each of the plurality of computing devices during the same time based on the temperature limit indicator being the lower temperature limit indicator; and
      activate the BIST circuit in less than each of plurality of computing devices during the same time based on the temperature limit indicator being the higher temperature limit indicator.
6. The processor-based system of clause 5, wherein:
   the one or more temperature thresholds further comprise a second temperature threshold higher than the first temperature threshold;
   the one or more thermal manager circuits are each configured to:
      compare the at least one of the maximum temperature and the temperature change rate to the first temperature threshold and the second temperature threshold;
      generate the temperature limit indicator by being configured to:
         generate the temperature limit indicator as the higher temperature limit indicator based on the comparison of the at least one of the maximum temperature and the temperature change rate being greater than the second temperature threshold; and
         by being further configured to generate the temperature limit indicator as an intermediate temperature limit indicator based on the comparison of the at least one of the maximum temperature and the temperature change rate being greater than the first temperature threshold and the at least one of the maximum temperature and the temperature change rate being less than the second temperature threshold; and
   the safety manager circuit is configured to, in response to test mode indicator indicating the test mode, selectively control the activation of the BIST circuit in each of the plurality of computing devices by being configured to:
      activate the BIST circuit in only one (1) of the plurality of computing devices during the same time based on the temperature limit indicator being the higher temperature limit indicator; and
      by being further configured to activate the BIST circuit in more than one (1) of the plurality of computing devices but less than all of the plurality of computing devices during the same time, based on the temperature limit indicator being the intermediate temperature limit indicator.
7. The processor-based system of clause 5, wherein:
   the first temperature threshold comprises a first maximum temperature threshold; and
   the one or more thermal manager circuits are each configured to:
      compare the maximum temperature to the first maximum temperature threshold; and
      generate the temperature limit indicator by being configured to:
         generate the temperature limit indicator as the lower temperature limit indicator based on the comparison of the maximum temperature being less than the first maximum temperature threshold; and
         generate the temperature limit indicator as the higher temperature limit indicator based on the comparison of the maximum temperature and being greater than the first maximum temperature threshold.
8. The processor-based system of clause 7, wherein the first maximum temperature threshold is fifty (50) degrees Celsius.
9. The processor-based system of clause 7 or 8, wherein:
   the one or more temperature thresholds further comprise a second maximum temperature threshold higher than the first maximum temperature threshold;
   the one or more thermal manager circuits are each configured to:
      compare the maximum temperature to the first maximum temperature threshold and the second maximum temperature threshold; and
      generate the temperature limit indicator by being configured to:
         generate the temperature limit indicator as the higher temperature limit indicator based on the comparison of the maximum temperature being greater than the second maximum temperature threshold; and
         by being further configured to generate the temperature limit indicator as an intermediate temperature limit indicator based on the comparison of the maximum temperature being greater than the first maximum temperature threshold and the maximum temperature being less than the second maximum temperature threshold; and
   the safety manager circuit is configured to, in response to test mode indicator indicating the test mode, selectively control the activation of the BIST circuit in each of the plurality of computing devices by being configured to:
      activate the BIST circuit in only one (1) of the plurality of computing devices during the same time based on the temperature limit indicator being the higher temperature limit indicator; and
      by being further configured to activate the BIST circuit in more than one (1) of the plurality of computing devices but less than all of the plurality of computing devices during the same time, based on the temperature limit indicator being the intermediate temperature limit indicator.
10. The processor-based system of clause 9, wherein:
   the first maximum temperature threshold is fifty (50) degrees Celsius; and
   the second maximum temperature threshold is eighty-five (85) degrees Celsius.
11. The processor-based system of clause 5 or 7, wherein:
   the one or more thermal manager circuits are each configured to:
      compare the temperature change rate to the first temperature threshold comprising a first temperature change rate threshold; and
      generate the temperature limit indicator by being configured to:
         generate the temperature limit indicator as the lower temperature limit indicator based on the comparison of the temperature change rate being less than the first temperature change rate threshold; and
         generate the temperature limit indicator as the higher temperature limit indicator based on the comparison of the temperature change rate being greater than the first temperature change rate threshold.
12. The processor-based system of clause 11, wherein the first temperature change rate threshold is ten (10) degrees Celsius per millisecond (ms).
13. The processor-based system of clause 11 or 12, wherein:
   the one or more temperature thresholds further comprise a second temperature change rate threshold higher than the first temperature change rate threshold;
   the one or more thermal manager circuits are each configured to:
      compare the temperature change rate to the first temperature change rate threshold and the second temperature change rate threshold; and
      generate the temperature limit indicator by being configured to:
         generate the temperature limit indicator as the higher temperature limit indicator based on the comparison of the temperature change rate being greater than the second temperature change rate threshold; and
         by being further configured to generate the temperature limit indicator as an intermediate temperature limit indicator based on the comparison of the temperature change rate being greater than the first temperature change rate threshold and the temperature change rate being less than the second temperature change rate threshold; and
   the safety manager circuit is configured to, in response to test mode indicator indicating the test mode, selectively control the activation of the BIST circuit in each of the plurality of computing devices by being configured to:
      activate the BIST circuit in only one (1) of the plurality of computing devices during the same time based on the temperature limit indicator being the higher temperature limit indicator; and
      by being further configured to activate the BIST circuit in more than one (1) of the plurality of computing devices but less than all of the plurality of computing devices during the same time, based on the temperature limit indicator being the intermediate temperature limit indicator.
14. The processor-based system of clause 13, wherein:
   the first temperature change rate threshold is ten (10) degrees Celsius per millisecond (ms); and
   the second temperature change rate threshold is ten (10) degrees Celsius per 200 microseconds (μs).
15. The processor-based system of any of clauses 1-14, wherein:
   the one or more thermal manager circuits comprise a plurality of local thermal manager circuits each associated with a computing device of the plurality of computing devices;
   each of the plurality of local thermal manager circuits is configured to:
      receive the one or more temperatures as a temperature sensed from a temperature sensor associated with its assigned computing device;
      convert the received temperature to the maximum temperature comprising a local maximum temperature;
      compare the maximum temperature comprising the local maximum temperature to the one or more temperature thresholds comprising one or more local temperature thresholds; and
      generate the temperature limit indicator comprising a local temperature limit indicator based on the comparison of the local maximum temperature to the one or more temperature thresholds comprising the one or more local temperature thresholds; and
   the safety manager circuit is configured to, in response to the test mode indicator indicating the test mode:
      selectively control the activation of the BIST circuit associated with each of the plurality of computing devices, based on the local temperature limit indicator generated by each local thermal manager circuit of the plurality of local thermal manager circuits assigned to the BIST circuit.
16. The processor-based system of clause 15, wherein:
   the plurality of computing devices comprises a plurality of processors each comprising:
      a plurality of processor cores; and
      a logic BIST (LBIST) circuit configured to be activated to test the plurality of processor cores; and
   the safety manager circuit is configured to, in response to the test mode indicator indicating the test mode, selectively control the activation of the LBIST circuit in each of the plurality of processors, by being configured to:
      for each processor of the plurality of processors, selectively control activation of a number of processor cores in the processor that the LBIST circuit of the processor tests during the same time, based on the local temperature limit indicator generated by the local thermal manager circuit of the plurality of local thermal manager circuits assigned to the LBIST circuit.
17. The processor-based system of any of clauses 1-14, wherein:
   the one or more thermal manager circuits comprise a central thermal manager circuit;
   the central thermal manager circuit is configured to:
      receive the one or more temperatures sensed from the one or more temperature sensors in the IC each assigned to an environmental area of the IC;
      convert the received one or more temperatures to the maximum temperature comprising a central maximum temperature;
      compare the maximum temperature comprising the central maximum temperature to the one or more temperature thresholds comprising one or more central temperature thresholds; and
      generate the temperature limit indicator comprising a central temperature limit indicator based on the comparison of the central maximum temperature to the one or more central temperature thresholds; and
   the safety manager circuit is configured to, in response to the test mode indicator indicating the test mode:
      selectively control the activation of the BIST circuit in each of the plurality of computing devices based on the central temperature limit indicator generated by the central thermal manager circuit.
18. The processor-based system of clause 17, wherein:
   the one or more central temperature thresholds comprise a first central temperature threshold;
   the central thermal manager circuit is configured to:
      compare at least one of the central maximum temperature and a central temperature change rate to the first central temperature threshold; and
      generate the central temperature limit indicator by being configured to:
         generate the central temperature limit indicator as a central lower temperature limit indicator based on the comparison of the at least one of the central maximum temperature and the central temperature change rate being less than the first central temperature threshold; and
         generate the central temperature limit indicator as a central higher temperature limit indicator based on the comparison of the at least one of the central maximum temperature and the central temperature change rate being greater than the first central temperature threshold; and
   the safety manager circuit is configured to, in response to the test mode indicator indicating the test mode, selectively control the activation of the BIST circuit by being configured to:
      activate the BIST circuit in each of the plurality of computing devices during the same time based on the central temperature limit indicator being the central lower temperature limit indicator; and
      activate the BIST circuit in less than each of plurality of computing devices during the same time based on the central temperature limit indicator being the central higher temperature limit indicator.
19. The processor-based system of clause 15, wherein:
   the plurality of computing devices comprises a plurality of processors each comprising:
      a plurality of processor cores; and
      a logic BIST (LBIST) circuit configured to be activated to test the plurality of processor cores;
   the one or more thermal manager circuits further comprise a central thermal manager circuit;
   the central thermal manager circuit is configured to:
      receive one or more central temperatures sensed from the one or more temperature sensors in the IC each assigned to an environmental area of the IC;
      convert the received one or more central temperatures to a central maximum temperature;
      compare the central maximum temperature to one or more central temperature thresholds; and
      generate a central temperature limit indicator based on the comparison of the central maximum temperature to the one or more central temperature thresholds and based on the local temperature limit indicators generated by the plurality of local thermal manager circuits; and
   the safety manager circuit is further configured to, in response to the test mode indicator indicating the test mode:
      selectively control the activation of the BIST circuit in each of the plurality of computing devices based on the central temperature limit indicator generated by central thermal manager circuit.
20. The processor-based system of clause 19, wherein:
   the central thermal manager circuit is configured to:
      compare the central maximum temperature to a first central temperature threshold; and
      generate the central temperature limit indicator by being configured to:
         generate the central temperature limit indicator as a central lower temperature limit indicator based on the comparison of the central maximum temperature being less than the first central temperature threshold and based on the local temperature limit indicators generated by the plurality of local thermal manager circuits; and
         generate the central temperature limit indicator as a central higher temperature limit indicator based on the comparison of the central maximum temperature being greater than the first central temperature threshold and based on the local temperature limit indicators generated by the plurality of local thermal manager circuits; and
   the safety manager circuit is configured to, in response to the test mode indicator indicating the test mode, selectively control the activation of the BIST circuit in each of the plurality of computing devices by being configured to:
      activate the BIST circuit in each of the plurality of processors during the same time based on the temperature limit indicator being the central lower temperature limit indicator; and
      activate the BIST circuit in less than each of plurality of processors during the same time based on the central temperature limit indicator being the central higher temperature limit indicator.
21. The processor-based system in clause 20, wherein:
   the one or more temperature thresholds further comprise a second central temperature threshold higher than the first central temperature threshold;
   the central thermal manager circuit is configured to:
      compare the central maximum temperature to the first central temperature threshold and the second central temperature threshold; and
      generate the central temperature limit indicator by being configured to:
         generate the central temperature limit indicator as the central higher temperature limit indicator based on the comparison of the central maximum temperature being greater than the second central temperature threshold and based on the local temperature limit indicators generated by the plurality of local thermal manager circuits; and
         by being further configured to generate the central temperature limit indicator as a central intermediate temperature limit indicator based on the comparison of the central maximum temperature being greater than the first central temperature threshold and the central maximum temperature being less than the second central temperature threshold and based on the local temperature limit indicators generated by the plurality of local thermal manager circuits; and
   the safety manager circuit is configured to, in response to the test mode indicator indicating the test mode, selectively control the activation of the BIST circuit by being configured to:
      activate the BIST circuit in only one (1) of the plurality of processors during the same time based on the central temperature limit indicator being the central higher temperature limit indicator; and
      by being further configured to activate the BIST circuit in more than one (1) of the plurality of processors but less than all of the plurality of processors during the same time, based on the central temperature limit indicator being the central intermediate temperature limit indicator.
22. The processor-based system of clause 21, wherein:
   the BIST control system is further configured to:
      generate a temperature limit indicator interrupt in response to generating the temperature limit indicator; and
   the safety manager circuit is further configured to receive the temperature limit indicator in response to the temperature limit indicator interrupt.
23. The processor-based system of any of clauses 1-22 integrated into an IC chip.
24. The processor-based system of any of clauses 1-23, comprising a system-on-a-chip (SoC).
25. The processor-based system of any of clauses 1-24 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.
26. A method of controlling activation of built-in self-test (BIST) circuits in a processor-based system comprising a plurality of computing devices and a plurality of BIST circuits each associated with a computing device of the plurality of computing devices and configured to be activated to test its associated computing device, the method comprising:
   receiving one or more temperatures sensed from one or more temperature sensors in an integrated circuit (IC);
   converting the received one or more temperatures to at least one of a maximum temperature and a temperature change rate;
   comparing the at least one of the maximum temperature and the temperature change rate to one or more temperature thresholds;
   generating a temperature limit indicator based on the comparison of the at least one of the maximum temperature and the temperature change rate to the one or more temperature thresholds;
   receiving a test mode indicator indicating a test mode for the processor-based system; and
   in response to the test mode indicator indicating the test mode, selectively controlling activation of one or more of the plurality of BIST circuits each associated with a computing device of the plurality of computing devices, based on the generated temperature limit indicator.
27. The method of clause 26, wherein in response to the test mode indicator indicating the test mode, the method further comprises:
   applying a BIST control policy to the temperature limit indicator to generate a BIST control indicator; and
   wherein selectively control activation of the BIST circuit comprises selectively control activation of the BIST circuit in each of the plurality of computing devices based on the BIST control indicator.
28. The method of clause 26, wherein:
   receiving the one or more temperatures comprises receiving the one or more temperatures as a temperature sensed from a temperature sensor associated with an assigned computing device of the plurality of computing devices;
   converting the received temperature comprises converting the received temperature to the maximum temperature comprising a local maximum temperature;
   comparing the maximum temperature comprises comparing the local maximum temperature to the one or more temperature thresholds comprising one or more local temperature thresholds;
   generating the temperature limit indicator comprises generating a local temperature limit indicator based on the comparison of the local maximum temperature to the one or more temperature thresholds comprising the one or more local temperature thresholds; and
   in response to the test mode indicator indicating the test mode:
      selectively controlling the activation of the BIST circuit associated with each of the plurality of computing devices, based on the local temperature limit indicator generated by each local thermal manager circuit of a plurality of local thermal manager circuits assigned to the BIST circuit.
29. The method of clause 26, wherein:
   receiving the one or more temperatures comprises receiving the one or more temperatures sensed from the one or more temperature sensors in the IC each assigned to an environmental area of the IC;
   converting the received one or more temperatures comprises convert the received one or more temperatures to a central maximum temperature;
   comparing the maximum temperature comprises comparing the central maximum temperature to the one or more temperature thresholds comprising one or more central temperature thresholds; and
   generating the temperature limit indicator comprises generating a central temperature limit indicator based on the comparison of the central maximum temperature to the one or more central temperature thresholds; and
   in response to the test mode indicator indicating the test mode:
      selectively control the activation of the BIST circuit in each of the plurality of computing devices based on the central temperature limit indicator generated by the central thermal manager circuit.
30. The processor-based system of clause 28, further comprising:
   receiving one or more central temperatures sensed from the one or more temperature sensors in the IC each assigned to an environmental area of the IC;
   converting the received one or more central temperatures to a central maximum temperature;
   comparing the central maximum temperature to one or more central temperature thresholds;
   generating a central temperature limit indicator based on the comparison of the central maximum temperature to the one or more central temperature thresholds and based on the local temperature limit indicators generated by the plurality of local thermal manager circuits; and
   in response to the test mode indicator indicating the test mode:
      selectively control the activation of the BIST circuit in each of the plurality of computing devices based on the central temperature limit indicator generated by central thermal manager circuit.

What is claimed is:

1. A processor-based system comprising an integrated circuit (IC), comprising:
a plurality of computing devices, wherein each computing device of the plurality of computing devices comprises:
a plurality of built-in self-test (BIST) circuits each associated with a computing device of the plurality of computing devices, each BIST circuit of the plurality of BIST circuits configured to be activated to test its associated computing device; and
a BIST control system, comprising:
a safety manager circuit configured to selectively control activation of the BIST circuit of each of the plurality of computing devices; and
one or more thermal manager circuits each configured to:
receive one or more temperatures sensed from one or more temperature sensors in the IC;
convert the received one or more temperatures to at least one of a maximum temperature and a temperature change rate;
compare the at least one of the maximum temperature and the temperature change rate to one or more temperature thresholds; and
generate a temperature limit indicator based on the comparison of the at least one of the maximum temperature and the temperature change rate to the one or more temperature thresholds;
the safety manager circuit configured to:
receive a test mode indicator indicating a test mode for the processor-based system; and
in response to the test mode indicator indicating the test mode:
selectively control the activation of the BIST circuit associated with each of the plurality of computing devices based on the temperature limit indicator generated by each of the one or more thermal manager circuits.

2. The processor-based system of claim 1, wherein:
each of the one or more thermal manager circuits comprises:
a temperature processing circuit configured to:
dynamically receive the one or more temperatures sensed from the one or more temperature sensors in the IC; and
a temperature limit generation circuit configured to:
dynamically compare the at least one of the maximum temperature and the temperature change rate to the one or more temperature thresholds; and
dynamically generate the temperature limit indicator based on the comparison of the at least one of the maximum temperature and the temperature change rate to the one or more temperature thresholds; and
the safety manager circuit is configured to, in response to the test mode indicator indicating the test mode:
dynamically selectively control the activation of the BIST circuit in each of the plurality of computing devices based on the temperature limit indicator generated by each of the one or more thermal manager circuits.

3. The processor-based system of claim 1, wherein the one or more thermal manager circuits are each configured to, in response to the test mode indicator indicating the test mode:
receive the one or more temperatures sensed from the one or more temperature sensors in the IC;
convert the received one or more temperatures to the at least one of the maximum temperature and the temperature change rate;
compare the at least one of the maximum temperature and the temperature change rate to the one or more temperature thresholds; and
generate the temperature limit indicator based on the comparison of the at least one of the maximum temperature and the temperature change rate to the one or more temperature thresholds.

4. The processor-based system of claim 1, wherein in response to the test mode indicator indicating the test mode, the safety manager circuit is further configured to, for each temperature limit indicator generated by each of the one or more thermal manager circuits:
apply a BIST control policy to the temperature limit indicator to generate a BIST control indicator; and
selectively control activation of the BIST circuit in each of the plurality of computing devices based on the BIST control indicator.

5. The processor-based system of claim 1, wherein:
the one or more temperature thresholds comprise a first temperature threshold;
the one or more thermal manager circuits are each configured to:
compare the at least one of the maximum temperature and the temperature change rate to the first temperature threshold; and
generate the temperature limit indicator by being configured to:
generate the temperature limit indicator as a lower temperature limit indicator based on the comparison of the at least one of the maximum temperature and the temperature change rate being less than the first temperature threshold; and
generate the temperature limit indicator as a higher temperature limit indicator based on the comparison of the at least one of the maximum temperature and the temperature change rate being greater than the first temperature threshold; and
the safety manager circuit is configured to, in response to test mode indicator indicating the test mode, selectively control activation of the BIST circuit by being configured to:
activate the BIST circuit in each of the plurality of computing devices during the same time based on the temperature limit indicator being the lower temperature limit indicator; and
activate the BIST circuit in less than each of plurality of computing devices during the same time based on the temperature limit indicator being the higher temperature limit indicator.

6. The processor-based system of claim 5, wherein:
the one or more temperature thresholds further comprise a second temperature threshold higher than the first temperature threshold;
the one or more thermal manager circuits are each configured to:
compare the at least one of the maximum temperature and the temperature change rate to the first temperature threshold and the second temperature threshold;
generate the temperature limit indicator by being configured to:
generate the temperature limit indicator as the higher temperature limit indicator based on the comparison of the at least one of the maximum temperature and the temperature change rate being greater than the second temperature threshold; and
by being further configured to generate the temperature limit indicator as an intermediate temperature limit indicator based on the comparison of the at least one of the maximum temperature and the temperature change rate being greater than the first temperature threshold and the at least one of the maximum temperature and the temperature change rate being less than the second temperature threshold; and
the safety manager circuit is configured to, in response to test mode indicator indicating the test mode, selectively control the activation of the BIST circuit in each of the plurality of computing devices by being configured to:
activate the BIST circuit in only one (1) of the plurality of computing devices during the same time based on the temperature limit indicator being the higher temperature limit indicator; and
by being further configured to activate the BIST circuit in more than one (1) of the plurality of computing devices but less than all of the plurality of computing devices during the same time, based on the temperature limit indicator being the intermediate temperature limit indicator.

7. The processor-based system of claim 5, wherein:
the first temperature threshold comprises a first maximum temperature threshold; and
the one or more thermal manager circuits are each configured to:
compare the maximum temperature to the first maximum temperature threshold; and
generate the temperature limit indicator by being configured to:
generate the temperature limit indicator as the lower temperature limit indicator based on the comparison of the maximum temperature being less than the first maximum temperature threshold; and
generate the temperature limit indicator as the higher temperature limit indicator based on the comparison of the maximum temperature and being greater than the first maximum temperature threshold.

8. The processor-based system of claim 7, wherein the first maximum temperature threshold is fifty (50) degrees Celsius.

9. The processor-based system of claim 7, wherein:
the one or more temperature thresholds further comprise a second maximum temperature threshold higher than the first maximum temperature threshold;
the one or more thermal manager circuits are each configured to:
compare the maximum temperature to the first maximum temperature threshold and the second maximum temperature threshold; and
generate the temperature limit indicator by being configured to:
generate the temperature limit indicator as the higher temperature limit indicator based on the comparison of the maximum temperature being greater than the second maximum temperature threshold; and
by being further configured to generate the temperature limit indicator as an intermediate temperature limit indicator based on the comparison of the maximum temperature being greater than the first maximum temperature threshold and the maximum temperature being less than the second maximum temperature threshold; and
the safety manager circuit is configured to, in response to test mode indicator indicating the test mode, selectively control the activation of the BIST circuit in each of the plurality of computing devices by being configured to:
activate the BIST circuit in only one (1) of the plurality of computing devices during the same time based on the temperature limit indicator being the higher temperature limit indicator; and
by being further configured to activate the BIST circuit in more than one (1) of the plurality of computing devices but less than all of the plurality of computing devices during the same time, based on the temperature limit indicator being the intermediate temperature limit indicator.

10. The processor-based system of claim 9, wherein:
the first maximum temperature threshold is fifty (50) degrees Celsius; and
the second maximum temperature threshold is eighty-five (85) degrees Celsius.

11. The processor-based system of claim 5, wherein:
the one or more thermal manager circuits are each configured to:
compare the temperature change rate to the first temperature threshold comprising a first temperature change rate threshold; and
generate the temperature limit indicator by being configured to:
generate the temperature limit indicator as the lower temperature limit indicator based on the comparison of the temperature change rate being less than the first temperature change rate threshold; and
generate the temperature limit indicator as the higher temperature limit indicator based on the comparison of the temperature change rate being greater than the first temperature change rate threshold.

12. The processor-based system of claim 11, wherein the first temperature change rate threshold is ten (10) degrees Celsius per millisecond (ms).

13. The processor-based system of claim 11, wherein:
the one or more temperature thresholds further comprise a second temperature change rate threshold higher than the first temperature change rate threshold;
the one or more thermal manager circuits are each configured to:
compare the temperature change rate to the first temperature change rate threshold and the second temperature change rate threshold; and
generate the temperature limit indicator by being configured to:
generate the temperature limit indicator as the higher temperature limit indicator based on the comparison of the temperature change rate being greater than the second temperature change rate threshold; and
by being further configured to generate the temperature limit indicator as an intermediate temperature limit indicator based on the comparison of the temperature change rate being greater than the first temperature change rate threshold and the temperature change rate being less than the second temperature change rate threshold; and
the safety manager circuit is configured to, in response to test mode indicator indicating the test mode, selectively control the activation of the BIST circuit in each of the plurality of computing devices by being configured to:
activate the BIST circuit in only one (1) of the plurality of computing devices during the same time based on the temperature limit indicator being the higher temperature limit indicator; and
by being further configured to activate the BIST circuit in more than one (1) of the plurality of computing devices but less than all of the plurality of computing devices during the same time, based on the temperature limit indicator being the intermediate temperature limit indicator.

14. The processor-based system of claim 13, wherein:
the first temperature change rate threshold is ten (10) degrees Celsius per millisecond (ms); and
the second temperature change rate threshold is ten (10) degrees Celsius per 200 microseconds (μs).

15. The processor-based system of claim 1, wherein:
the one or more thermal manager circuits comprise a plurality of local thermal manager circuits each associated with a computing device of the plurality of computing devices;
each of the plurality of local thermal manager circuits is configured to:
receive the one or more temperatures as a temperature sensed from a temperature sensor associated with its assigned computing device;
convert the received temperature to the maximum temperature comprising a local maximum temperature;
compare the maximum temperature comprising the local maximum temperature to the one or more temperature thresholds comprising one or more local temperature thresholds; and
generate the temperature limit indicator comprising a local temperature limit indicator based on the comparison of the local maximum temperature to the one or more temperature thresholds comprising the one or more local temperature thresholds; and
the safety manager circuit is configured to, in response to the test mode indicator indicating the test mode:
selectively control the activation of the BIST circuit associated with each of the plurality of computing devices, based on the local temperature limit indicator generated by each local thermal manager circuit of the plurality of local thermal manager circuits assigned to the BIST circuit.

16. The processor-based system of claim 15, wherein:
the plurality of computing devices comprises a plurality of processors each comprising:
a plurality of processor cores; and
a logic BIST (LBIST) circuit configured to be activated to test the plurality of processor cores; and
the safety manager circuit is configured to, in response to the test mode indicator indicating the test mode, selectively control the activation of the LBIST circuit in each of the plurality of processors, by being configured to:
for each processor of the plurality of processors, selectively control activation of a number of processor cores in the processor that the LBIST circuit of the processor tests during the same time, based on the local temperature limit indicator generated by the local thermal manager circuit of the plurality of local thermal manager circuits assigned to the LBIST circuit.

17. The processor-based system of claim 1, wherein:
the one or more thermal manager circuits comprise a central thermal manager circuit;
the central thermal manager circuit is configured to:
receive the one or more temperatures sensed from the one or more temperature sensors in the IC each assigned to an environmental area of the IC;
convert the received one or more temperatures to the maximum temperature comprising a central maximum temperature;
compare the maximum temperature comprising the central maximum temperature to the one or more temperature thresholds comprising one or more central temperature thresholds; and
generate the temperature limit indicator comprising a central temperature limit indicator based on the comparison of the central maximum temperature to the one or more central temperature thresholds; and
the safety manager circuit is configured to, in response to the test mode indicator indicating the test mode:
selectively control the activation of the BIST circuit in each of the plurality of computing devices based on the central temperature limit indicator generated by the central thermal manager circuit.

18. The processor-based system of claim 17, wherein:
the one or more central temperature thresholds comprise a first central temperature threshold;
the central thermal manager circuit is configured to:
compare at least one of the central maximum temperature and a central temperature change rate to the first central temperature threshold; and
generate the central temperature limit indicator by being configured to:
generate the central temperature limit indicator as a central lower temperature limit indicator based on the comparison of the at least one of the central maximum temperature and the central temperature change rate being less than the first central temperature threshold; and
generate the central temperature limit indicator as a central higher temperature limit indicator based on the comparison of the at least one of the central maximum temperature and the central temperature change rate being greater than the first central temperature threshold; and
the safety manager circuit is configured to, in response to the test mode indicator indicating the test mode, selectively control the activation of the BIST circuit by being configured to:
activate the BIST circuit in each of the plurality of computing devices during the same time based on the central temperature limit indicator being the central lower temperature limit indicator; and
activate the BIST circuit in less than each of plurality of computing devices during the same time based on the central temperature limit indicator being the central higher temperature limit indicator.

19. The processor-based system of claim 15, wherein:
the plurality of computing devices comprises a plurality of processors each comprising:
a plurality of processor cores; and
a logic BIST (LBIST) circuit configured to be activated to test the plurality of processor cores;
the one or more thermal manager circuits further comprise a central thermal manager circuit;
the central thermal manager circuit is configured to:
receive one or more central temperatures sensed from the one or more temperature sensors in the IC each assigned to an environmental area of the IC;
convert the received one or more central temperatures to a central maximum temperature;
compare the central maximum temperature to one or more central temperature thresholds; and
generate a central temperature limit indicator based on the comparison of the central maximum temperature to the one or more central temperature thresholds and based on the local temperature limit indicators generated by the plurality of local thermal manager circuits; and
the safety manager circuit is further configured to, in response to the test mode indicator indicating the test mode:
selectively control the activation of the BIST circuit in each of the plurality of computing devices based on the central temperature limit indicator generated by central thermal manager circuit.

20. The processor-based system of claim 19, wherein:
the central thermal manager circuit is configured to:
compare the central maximum temperature to a first central temperature threshold; and
generate the central temperature limit indicator by being configured to:
generate the central temperature limit indicator as a central lower temperature limit indicator based on the comparison of the central maximum temperature being less than the first central temperature threshold and based on the local temperature limit indicators generated by the plurality of local thermal manager circuits; and
generate the central temperature limit indicator as a central higher temperature limit indicator based on the comparison of the central maximum temperature being greater than the first central temperature threshold and based on the local temperature limit indicators generated by the plurality of local thermal manager circuits; and
the safety manager circuit is configured to, in response to the test mode indicator indicating the test mode, selectively control the activation of the BIST circuit in each of the plurality of computing devices by being configured to:
activate the BIST circuit in each of the plurality of processors during the same time based on the temperature limit indicator being the central lower temperature limit indicator; and
activate the BIST circuit in less than each of plurality of processors during the same time based on the central temperature limit indicator being the central higher temperature limit indicator.

21. The processor-based system in claim 20, wherein:
the one or more temperature thresholds further comprise a second central temperature threshold higher than the first central temperature threshold;
the central thermal manager circuit is configured to:
compare the central maximum temperature to the first central temperature threshold and the second central temperature threshold; and
generate the central temperature limit indicator by being configured to:
generate the central temperature limit indicator as the central higher temperature limit indicator based on the comparison of the central maximum temperature being greater than the second central temperature threshold and based on the local temperature limit indicators generated by the plurality of local thermal manager circuits; and
by being further configured to generate the central temperature limit indicator as a central intermediate temperature limit indicator based on the comparison of the central maximum temperature being greater than the first central temperature threshold and the central maximum temperature being less than the second central temperature threshold and based on the local temperature limit indicators generated by the plurality of local thermal manager circuits; and
the safety manager circuit is configured to, in response to the test mode indicator indicating the test mode, selectively control the activation of the BIST circuit by being configured to:
activate the BIST circuit in only one (1) of the plurality of processors during the same time based on the central temperature limit indicator being the central higher temperature limit indicator; and
by being further configured to activate the BIST circuit in more than one (1) of the plurality of processors but less than all of the plurality of processors during the same time, based on the central temperature limit indicator being the central intermediate temperature limit indicator.

22. The processor-based system of claim 1, wherein:
the BIST control system is further configured to:
generate a temperature limit indicator interrupt in response to generating the temperature limit indicator; and
the safety manager circuit is further configured to receive the temperature limit indicator in response to the temperature limit indicator interrupt.

23. The processor-based system of claim 1 integrated into an IC chip.

24. The processor-based system of claim 1, comprising a system-on-a-chip (SoC).

25. The processor-based system of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

26. A method of controlling activation of built-in self-test (BIST) circuits in a processor-based system comprising a plurality of computing devices and a plurality of BIST circuits each associated with a computing device of the plurality of computing devices and configured to be activated to test its associated computing device, the method comprising:
receiving one or more temperatures sensed from one or more temperature sensors in an integrated circuit (IC);
converting the received one or more temperatures to at least one of a maximum temperature and a temperature change rate;
comparing the at least one of the maximum temperature and the temperature change rate to one or more temperature thresholds;
generating a temperature limit indicator based on the comparison of the at least one of the maximum temperature and the temperature change rate to the one or more temperature thresholds;
receiving a test mode indicator indicating a test mode for the processor-based system; and
in response to the test mode indicator indicating the test mode, selectively controlling activation of one or more of the plurality of BIST circuits each associated with a computing device of the plurality of computing devices, based on the generated temperature limit indicator.

27. The method of claim 26, wherein in response to the test mode indicator indicating the test mode, the method further comprises:
applying a BIST control policy to the temperature limit indicator to generate a BIST control indicator; and
wherein selectively control activation of the BIST circuit comprises selectively control activation of the BIST circuit in each of the plurality of computing devices based on the BIST control indicator.

28. The method of claim 26, wherein:
receiving the one or more temperatures comprises receiving the one or more temperatures as a temperature sensed from a temperature sensor associated with an assigned computing device of the plurality of computing devices;
converting the received temperature comprises converting the received temperature to the maximum temperature comprising a local maximum temperature;
comparing the maximum temperature comprises comparing the local maximum temperature to the one or more temperature thresholds comprising one or more local temperature thresholds;
generating the temperature limit indicator comprises generating a local temperature limit indicator based on the comparison of the local maximum temperature to the one or more temperature thresholds comprising the one or more local temperature thresholds; and
in response to the test mode indicator indicating the test mode:
selectively controlling the activation of the BIST circuit associated with each of the plurality of computing devices, based on the local temperature limit indicator generated by each local thermal manager circuit of a plurality of local thermal manager circuits assigned to the BIST circuit.

29. The method of claim 26, wherein:
receiving the one or more temperatures comprises receiving the one or more temperatures sensed from the one or more temperature sensors in the IC each assigned to an environmental area of the IC;
converting the received one or more temperatures comprises convert the received one or more temperatures to a central maximum temperature;
comparing the maximum temperature comprises comparing the central maximum temperature to the one or more temperature thresholds comprising one or more central temperature thresholds; and
generating the temperature limit indicator comprises generating a central temperature limit indicator based on the comparison of the central maximum temperature to the one or more central temperature thresholds; and
in response to the test mode indicator indicating the test mode:
selectively control the activation of the BIST circuit in each of the plurality of computing devices based on the central temperature limit indicator generated by the central thermal manager circuit.

30. The processor-based system of claim 28, further comprising:
receiving one or more central temperatures sensed from the one or more temperature sensors in the IC each assigned to an environmental area of the IC;
converting the received one or more central temperatures to a central maximum temperature;
comparing the central maximum temperature to one or more central temperature thresholds;
generating a central temperature limit indicator based on the comparison of the central maximum temperature to the one or more central temperature thresholds and based on the local temperature limit indicators generated by the plurality of local thermal manager circuits; and
in response to the test mode indicator indicating the test mode:
selectively control the activation of the BIST circuit in each of the plurality of computing devices based on the central temperature limit indicator generated by central thermal manager circuit.
